(19) United States
(12) Patent Application Publication
(10) Pub. No.: US 2024/0055350 A1
(43) Pub. Date: Feb. 15, 2024

(54) ELECTRONIC DEVICES INCLUDING STACKS INCLUDING CONDUCTIVE STRUCTURES ISOLATED BY SLOT STRUCTURES, AND RELATED SYSTEMS AND METHODS

(71) Applicant: Micron Technology, Inc., Boise, ID (US)

(72) Inventors: Mark S. Swenson, Meridian, ID (US); Surendranath C. Eruvuru, Boise, ID (US); Lifang Xu, Boise, ID (US)

(21) Appl. No.: 17/819,538

(22) Filed: Aug. 12, 2022

(51) Int. Cl. H01L 23/528; H01L 27/11565; H01L 27/1157; H01L 27/11582; H01L 23/532; H01L 21/768

(52) U.S. Cl. CPC H01L 23/5283; H01L 27/11565; H01L 27/1157; H01L 27/11582; H01L 23/53295; H01L 21/76837

(57) ABSTRACT

An electronic device comprises a stack comprising an alternating sequence of conductive structures and insulative structures arranged in tiers, and at least one dielectric-filled slot extending vertically through the stack and extending in a first horizontal direction. The at least one dielectric-filled slot is defined between two internal sidewalls of the stack. The electronic device comprises additional dielectric-filled slots extending vertically through the stack and extending in a second horizontal direction transverse to the first horizontal direction, and isolation structures laterally interposed between the at least one dielectric-filled slot and the additional dielectric-filled slots. The isolation structures are laterally adjacent to the conductive structures of the stack, and at least some of the isolation structures are vertically adjacent to the insulative structures of the stack. Related systems and methods of forming the electronic devices are also disclosed.

### TECHNICAL FIELD

Embodiments of the disclosure relate to the field of electronic device design and fabrication. More particularly, the disclosure relates to electronic devices including stacks including conductive structures isolated by slot structures (e.g., dielectric-filled slots), and related systems and methods of forming the electronic devices.

### BACKGROUND

A continuing goal of the electronics industry has been to increase the memory density (e.g., the number of memory cells per memory die) of memory devices, such as non-volatile memory devices (e.g., NAND Flash memory devices). One way of increasing memory density in non-volatile memory devices is to utilize vertical memory array (also referred to as a “three-dimensional (3D) memory array”) architectures. A conventional vertical memory array includes vertical memory strings extending through openings in one or more stack structures including tiers of conductive structures and insulative structures. Each vertical memory string may include at least one select device coupled in series to a serial combination of vertically-stacked memory cells. Such a configuration permits a greater number of switching devices (e.g., transistors) to be located in a unit of die area (i.e., length and width of active surface consumed) by building the array upwards (e.g., vertically) on a die, as compared to structures with conventional planar (e.g., two-dimensional) arrangements of transistors.

Vertical memory array architectures generally include electrical connections between the conductive structures of the tiers of the stack structures of the memory device and access lines (e.g., word lines) so that the memory cells of the vertical memory array can be uniquely selected for writing, reading, or erasing operations. One method of forming such an electrical connection includes forming so-called “staircase” (or “stair step”) structures at edges (e.g., horizontal ends) of the conductive structures of the stack structures of the memory device. The staircase structure includes individual “steps” defining contact regions of the conductive structures, upon which conductive contact structures can be positioned to provide electrical access to the conductive structures.

As feature packing densities have increased and margins for formation errors have decreased, conventional methods of forming the memory devices may result in undesirable current leaks (e.g., access line to source current leaks) and short circuits (between access lines of adjacent blocks) that can diminish desired memory device performance, reliability, and durability. For example, conventional methods of partitioning a preliminary stack structure including tiers of insulative structures and additional insulative structures into blocks and sub-blocks may result in undesirable conductive material depositions during subsequent processing of the preliminary stack structure (e.g., so called “replacement gate” or “gate last” processing of the preliminary stack structure to replace one or more portions of the additional insulative structures with conductive structures to form the stack structure of the memory device) that can effectuate undesirable leakage currents and short circuits.

### BRIEF DESCRIPTION OF THE DRAWINGS

FIGS. 1A through 5D are simplified, partial top-down views (i.e., FIGS. 1A, 2A, 3A, 4A, and 5A) and simplified, partial cross-sectional views (i.e., FIGS. 1B through 1D, 2B through 2E, 3B through 3D, 4B through 4D, and 5B through 5D) illustrating a method of forming an electronic device, in accordance with embodiments of the disclosure;

FIGS. 6A through 7D are simplified, partial top-down views (i.e., FIGS. 6A and 7A) and simplified, partial cross-sectional views (i.e., FIGS. 6B through 6D and 7B through 7D) illustrating a method of forming an electronic device, in accordance with additional embodiments of the disclosure;

FIG. 8 is a partial cutaway perspective view of an electronic device, in accordance with embodiments of the disclosure;

FIG. 9 is a block diagram of a system, in accordance with embodiments of the disclosure; and

FIG. 10 is a block diagram of a processor-based system, in accordance with embodiments of the disclosure.

### DETAILED DESCRIPTION

Electronic devices (e.g., apparatus, microelectronic devices) and systems (e.g., electronic systems) according to embodiments of the disclosure include a stack comprising an alternating sequence of conductive structures and insulative structures arranged in tiers. At least one dielectric-filled slot extends vertically through the stack and extends in a first horizontal direction and additional dielectric-filled slots extend vertically through the stack and extend in a second horizontal direction transverse to the first horizontal direction. The at least one dielectric-filled slot is defined between two internal sidewalls of materials of the stack. The electronic device comprises isolation structures (e.g., one or more dielectric materials within isolation regions) laterally interposed between the at least one dielectric-filled slot and the additional dielectric-filled slots. The isolation structures are laterally adjacent to the conductive structures (e.g., access lines) of the stack, and at least some of the isolation structures are vertically adjacent to the insulative structures of the stack. In additional embodiments, dielectric block structures (e.g., discrete structures segmented by isolation regions) are defined between two internal sidewalls of the materials of the stack and spaced apart from one another in the first horizontal direction, and dielectric-filled slots extend vertically through the stack and extend in a second horizontal direction that is substantially orthogonal to the first horizontal direction. The isolation structures separate the dielectric block structures from the dielectric-filled slots, and the isolation structures are at an elevational level of the conductive structures of the stack.

Fabrication of the electronic devices according to embodiments of the disclosure includes forming at least one slot through the stack to expose a source and forming additional slots through the stack and extending in a second horizontal direction transverse to the first horizontal direction. Isolation structures may be laterally interposed between the at least one slot and the additional slots, and portions of the additional insulative structures may be replaced with conductive material to form conductive structures. In some embodiments, the additional slots may be formed substantially simultaneously with forming the at least one slot. Openings (e.g., support structure openings) may be formed during formation of one or more of the at least one slot and the additional slots. Alternatively, the additional slots may be formed after forming the at least one slot and the openings.

In contrast to conventional electronic devices, the electronic devices according to embodiments of the disclosure include the isolation structures laterally interposed between the at least one dielectric-filled slot and the additional dielectric-filled slots. By forming the isolation structures to laterally separate the slots, unintentional micro-trenching in the final stack may be substantially reduced (e.g., substantially prevented) by substantially reducing ion deflection off of sidewalls defining the slots near the intersections during formation of the slots by eliminating corners between the converging slots. In addition, laterally separating the slots near the intersections may substantially reduce (e.g., substantially prevent) so-called “overetch” near the intersections during processing. Further, damage to the materials of pillars and support structures, also called “clipping,” may be reduced by providing the isolation structures to laterally separate the slots near the intersections.

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional electronic device fabrication techniques employed in the industry. In addition, the description provided below does not form a complete process flow for manufacturing an electronic device (e.g., a memory device, such as 3D NAND Flash memory device). The structures described below do not form a complete electronic device. Only those process acts and structures necessary to understand the embodiments of the disclosure are described in detail below. Additional acts to form a complete electronic device from the structures may be performed by conventional fabrication techniques.

Unless otherwise indicated, the materials described herein may be formed by conventional techniques including, but not limited to, spin coating, blanket coating, chemical vapor deposition (CVD), atomic layer deposition (ALD), plasma enhanced ALD, physical vapor deposition (PVD) (including sputtering, evaporation, ionized PVD, and/or plasma-enhanced CVD), or epitaxial growth. Alternatively, the materials may be grown in situ. Depending on the specific material to be formed, the technique for depositing or growing the material may be selected by a person of ordinary skill in the art. The removal of materials may be accomplished by any suitable technique including, but not limited to, etching (e.g., dry etching, wet etching, vapor etching), ion milling, abrasive planarization (e.g., chemical-mechanical planarization), or other known methods unless the context indicates otherwise.

Drawings presented herein are for illustrative purposes only, and are not meant to be actual views of any particular material, component, structure, electronic device, or electronic system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, the singular forms “a,” “an,” and “the” are intended to include the plural forms as well, unless the context clearly indicates otherwise.

As used herein, “and/or” includes any and all combinations of one or more of the associated listed items.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the terms “vertical,” “longitudinal,” “horizontal,” and “lateral” are in reference to a major plane of a structure and are not necessarily defined by Earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure.

As used herein, reference to an element as being “on” or “over” another element means and includes the element being directly on top of, directly adjacent to (e.g., directly laterally adjacent to, directly vertically adjacent to), directly underneath, or in direct contact with the other element. It also includes the element being indirectly on top of, indirectly adjacent to (e.g., indirectly laterally adjacent to, indirectly vertically adjacent to), indirectly underneath, or near the other element, with other elements present therebetween. In contrast, when an element is referred to as being “directly on” or “directly adjacent to” another element, there are no intervening elements present.

As used herein, features (e.g., regions, materials, structures, devices) described as “neighboring” one another means and includes features of the disclosed identity (or identities) that are located most proximate (e.g., closest to) one another. Additional features (e.g., additional regions, additional materials, additional structures, additional devices) not matching the disclosed identity (or identities) of the “neighboring” features may be disposed between the “neighboring” features. Stated another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 108.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the term “electronic device” includes, without limitation, a memory device, as well as a semiconductor device which may or may not incorporate memory, such as a logic device, a processor device, or a radiofrequency (RF) device. Further, an electronic device may incorporate memory in addition to other functions such as, for example, a so-called “system on a chip” (SoC) including a processor and memory, or an electronic device including logic and memory. The electronic device may, for example, be a 3D electronic device, such as a 3D NAND Flash memory device.

As used herein, the term “conductive material” means and includes an electrically conductive material. The conductive material may include one or more of a doped polysilicon, undoped polysilicon, a metal, an alloy, a conductive metal oxide, a conductive metal nitride, a conductive metal silicide, and a conductively doped semiconductor material. By way of example only, the conductive material may be one or more of tungsten (W), tungsten nitride (WN_{y}), nickel (Ni), tantalum (Ta), tantalum nitride (TaN_{y}), tantalum silicide (TaSiₓ), platinum (Pt), copper (Cu), silver (Ag), gold (Au), aluminum (Al), molybdenum (Mo), titanium (Ti), titanium nitride (TiN_{y}), titanium silicide (TiSiₓ), titanium silicon nitride (TiSiₓN_{y}), titanium aluminum nitride (TiAlₓN_{y}), molybdenum nitride (MoNₓ), iridium (Ir), iridium oxide (IrO_{z}), ruthenium (Ru), ruthenium oxide (RuO_{z}), n-doped polysilicon, p-doped polysilicon, undoped polysilicon, and conductively doped silicon.

As used herein, a “conductive structure” means and includes a structure formed of and including one or more conductive materials.

As used herein, “insulative material” means and includes an electrically insulative material, such as one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

As used herein, an “insulative structure” means and includes a structure formed of and including an insulative material.

As used herein, the terms “opening” and “slot” mean and include a volume extending through at least one structure or at least one material, leaving a void (e.g., gap) in that at least one structure or at least one material, or a volume extending between structures or materials, leaving a gap between the structures or materials. Unless otherwise described, an “opening” and/or “slot” is not necessarily empty of material. That is, an “opening” and/or “slot” is not necessarily void space. An “opening” and/or “slot” formed in or between structures or materials may comprise structure(s) or material(s) other than that in or between which the opening is formed. And, structure(s) or material(s) “exposed” within an “opening” and/or “slot” is (are) not necessarily in contact with an atmosphere or non-solid environment. Structure(s) or material(s) “exposed” within an “opening” and/or “slot” may be adjacent or in contact with other structure(s) or material(s) that is (are) disposed within the “opening” and/or “slot.”

As used herein, the term “intersection” means and includes a location at which two or more features (e.g., regions, structures, materials, slots, trenches, devices) or, alternatively, two or more portions of a single feature meet. For example, an intersection between a first feature extending in a first direction (e.g., an X-direction) and a second feature extending in a second direction (e.g., a Y-direction) different than the first direction may be the location at which the first feature and the second feature meet.

As used herein, the term “intersection region” means and includes a region at which two or more features (e.g., regions, structures, materials, slots, trenches, devices) or, alternatively, two or more portions of a single feature may be proximal (e.g., approach) one another. For example, two or more features or portions of a single feature may be proximal one other within an intersection region, with or without meeting (e.g., connecting, adjoining) one another.

As used herein, the term “sacrificial,” when used in reference to a material or structure, means and includes a material or structure that is formed during a fabrication process but which is removed (e.g., substantially removed) prior to completion of the fabrication process.

As used herein, the terms “selectively removable” or “selectively etchable” mean and include a material that exhibits a greater etch rate responsive to exposure to a given etch chemistry and/or process conditions (collectively referred to as etch conditions) relative to another material exposed to the same etch chemistry and/or process conditions. For example, the material may exhibit an etch rate that is at least about five times greater than the etch rate of another material, such as an etch rate of about ten times greater, about twenty times greater, or about forty times greater than the etch rate of the another material. Etch chemistries and etch conditions for selectively etching a desired material may be selected by a person of ordinary skill in the art.

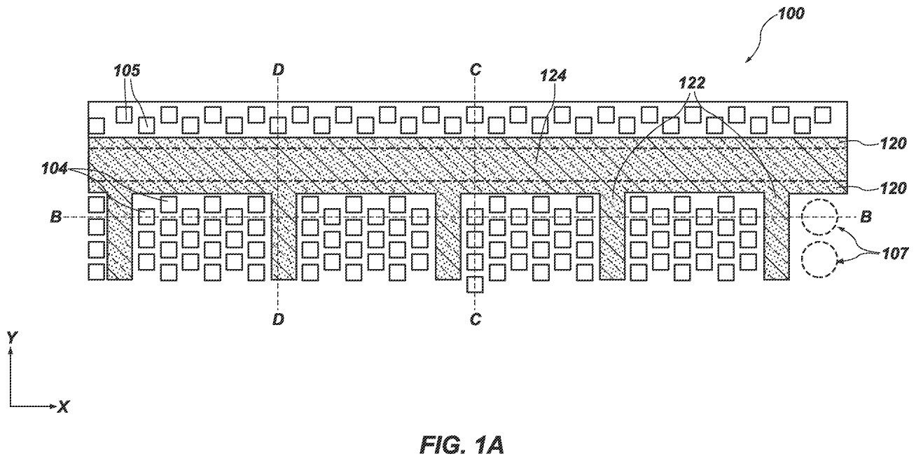

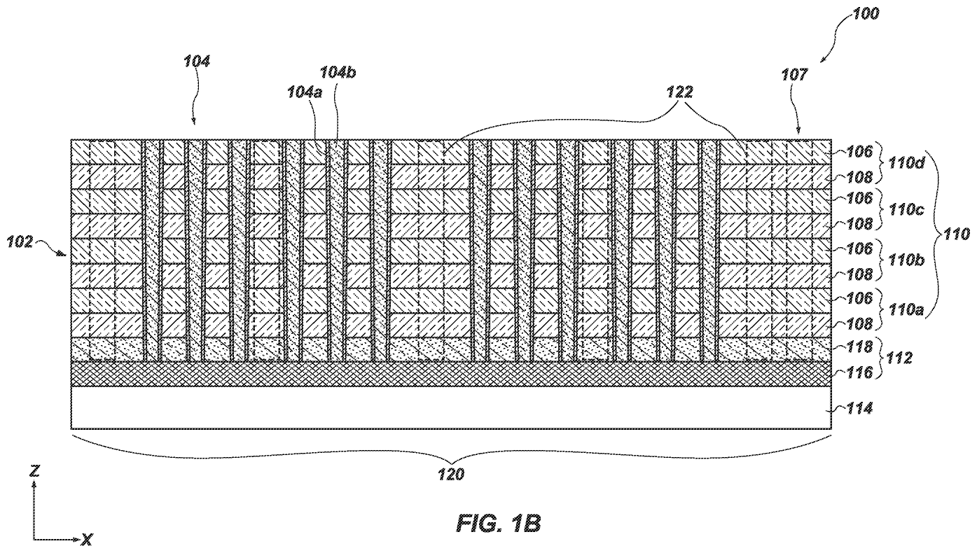

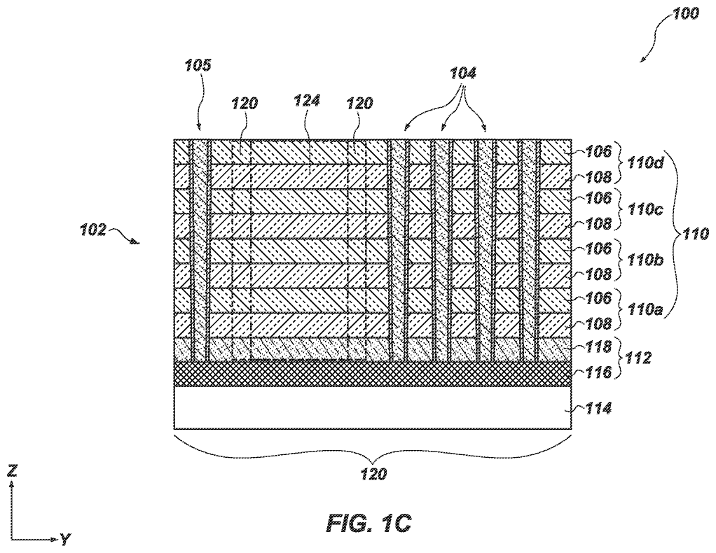

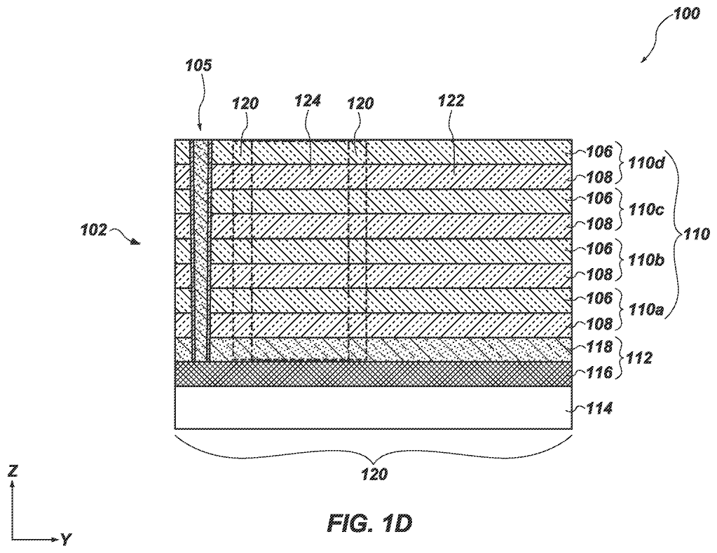

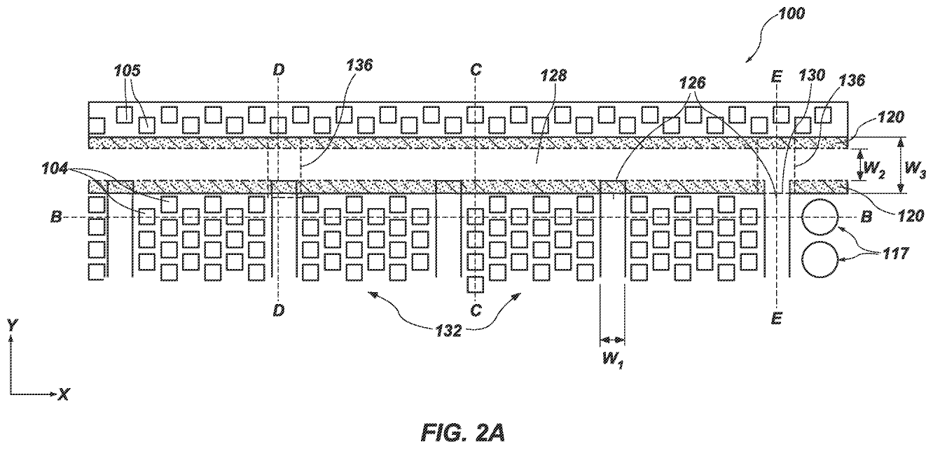

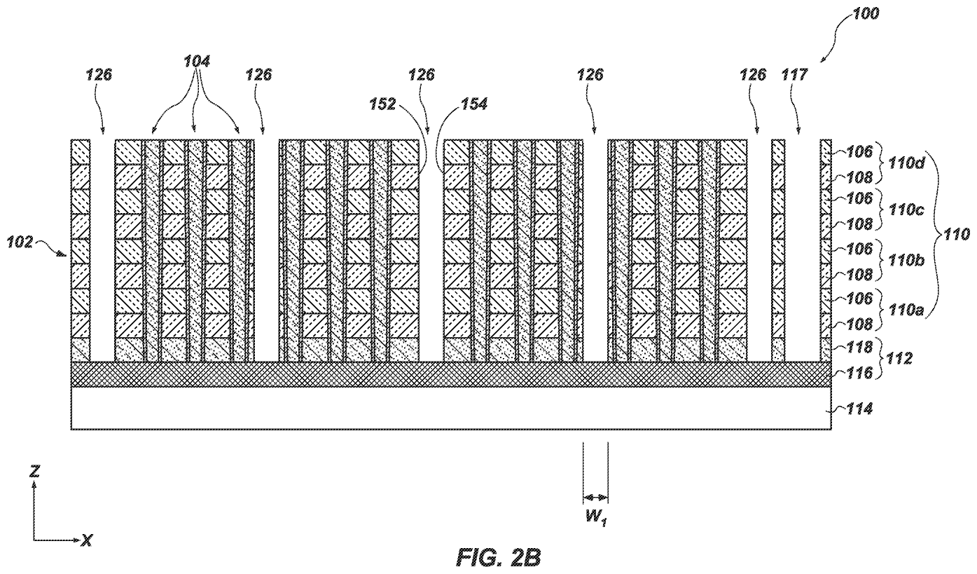

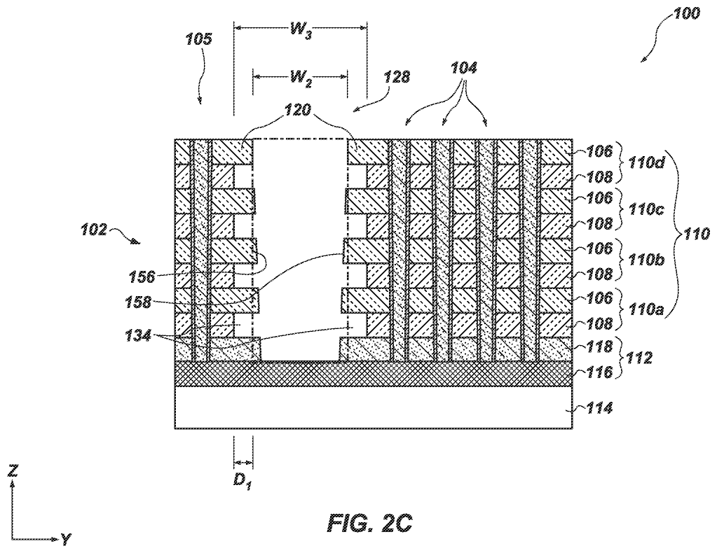

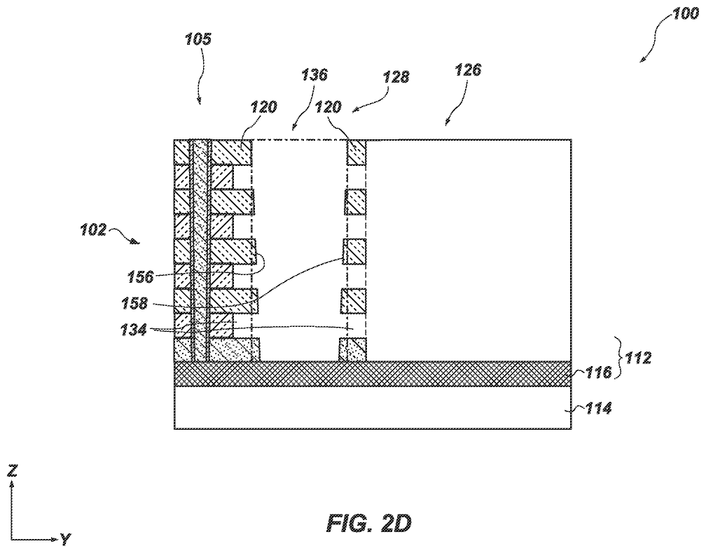

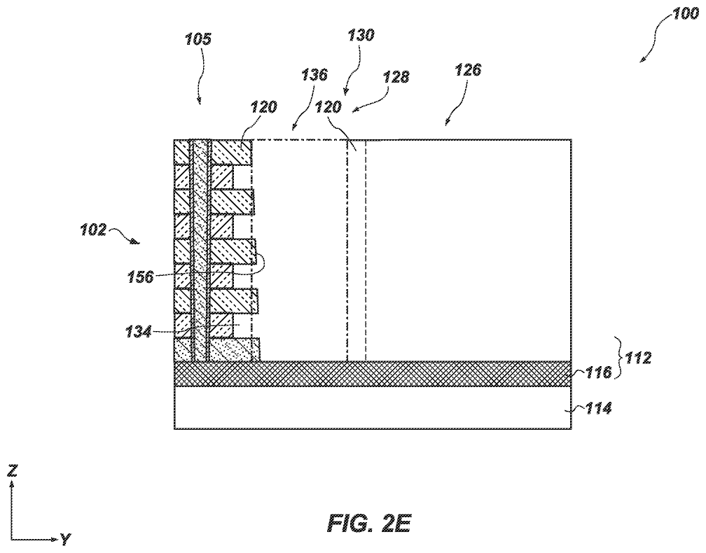

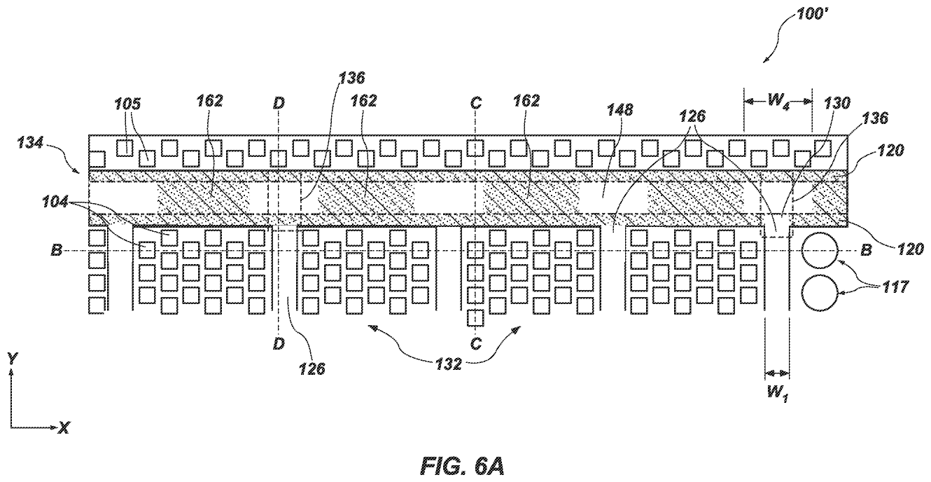

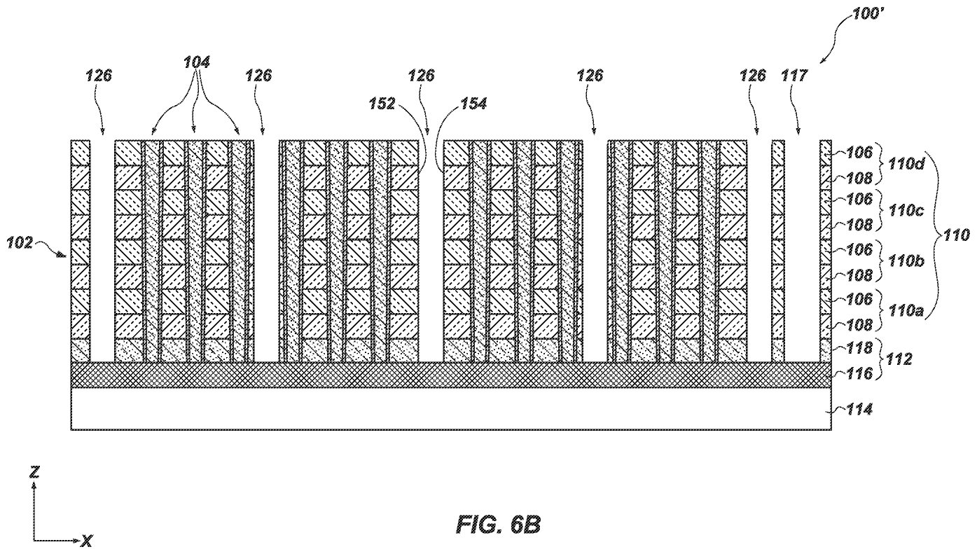

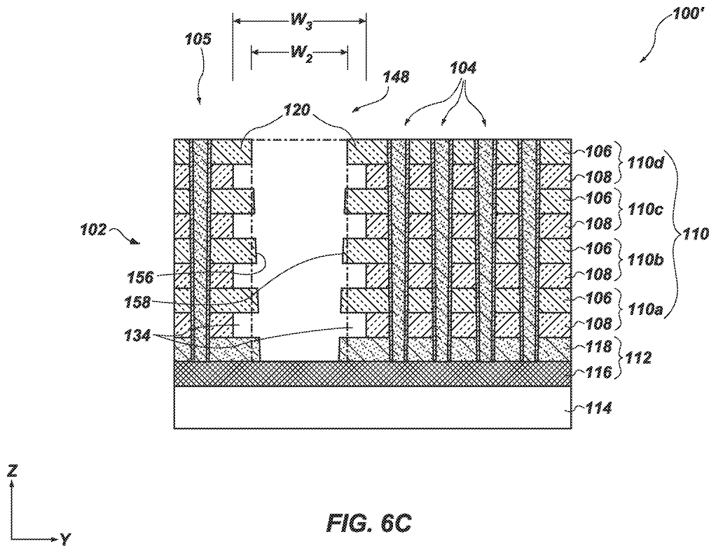

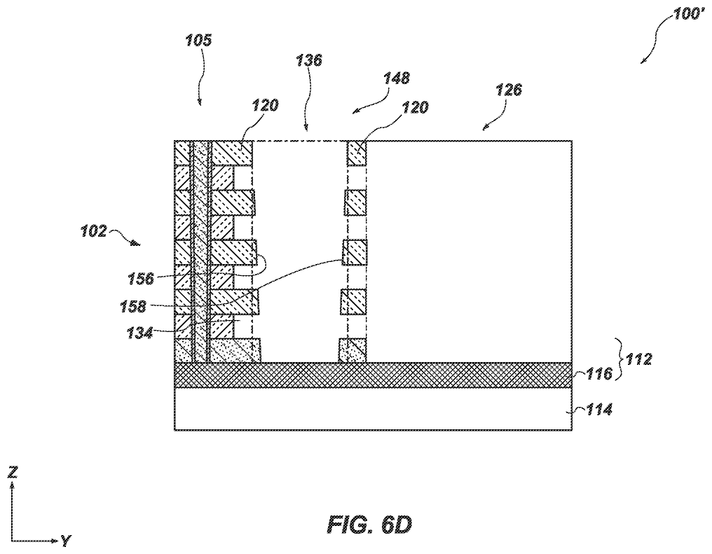

FIGS. 1A through 5D illustrate a method of forming an electronic device (e.g., a memory device, such as a 3D NAND Flash memory device), in accordance with embodiments of the disclosure. FIG. 1A is a simplified, partial top-down view of an electronic device 100. FIGS. 1B, 1C, and 1D are simplified cross-sectional views of the electronic device 100 taken along the B-B line, the C-C line, and the D-D line, respectively, of FIG. 1A. For clarity and ease of understanding of the drawings and related description, not all features depicted in one of FIGS. 1A through 1D are depicted in each of the others of FIGS. 1A through 1D, which applies equally to FIGS. 2A through 5D, respectively. For convenience in describing FIGS. 1A through 5D, a first direction may be defined as the X-direction and a second direction, which is orthogonal (e.g., perpendicular) to the first direction, as the Y-direction. A third direction, which is orthogonal (e.g., perpendicular) to each of the first direction and the second direction, may be defined as the Z-direction. Similar directions are shown in FIGS. 6A through 7D and FIG. 8, which are discussed in further detail below.

Referring to FIG. 1A, the electronic device 100 may be formed to include first pillars 104 and second pillars 105. The first pillars 104 and the second pillars 105 may extend vertically (e.g., in the Z-direction) through a stack 102 (FIGS. 1B and 1C). The first pillars 104 may be separated from the second pillars 105 by at least one second slot region 124 (e.g., a second trench region) extending in a first horizontal direction (e.g., the X-direction). Neighboring blocks of the first pillars 104 may be horizontally separated from one another by first slot regions 122 (e.g., first trench regions) extending in a second horizontal direction (e.g., the Y-direction) transverse to the first horizontal direction. The first pillars 104 may be horizontally aligned with one another in columns extending in the second horizontal direction. For clarity and ease of understanding the description, FIG. 1A illustrates a particular quantity of columns of the first pillars 104 between horizontally neighboring first slot regions 122. However, it will be understood that the electronic device 100 may include a greater quantity of columns of the first pillars 104 between the horizontally neighboring first slot regions 122 than those illustrated.

The electronic device 100 may include an isolation region 120 including one or more (e.g., two opposing) portions extending in the first horizontal direction and adjacent to elongated sides of the second slot region 124. The isolation region 120 may facilitate a desired horizontal distance between the second slot region 124 and each of the first pillars 104 and the second pillars 105, and to facilitate desired horizontal spacing (e.g., in the Y-direction) between the first slot regions 122 and the second slot region 124, as described in greater detail below. In other words, the isolation region 120 separates the first slot regions 122 from the second slot region 124. The isolation region 120 includes one or more areas designated for isolation structures subsequently formed within the opposing portions thereof. While two opposing portions of the isolation region 120 are shown throughout the drawings for clarity, the disclosure is not so limited, and the isolation region 120 may include only one (e.g., a single) portion adjacent to the second slot region 124, as well as adjacent to subsequent features formed within the second slot region 124. For example, one portion of the isolation region 120 may be formed to extend adjacent to the second slot region 124 between the second slot region 124 and the first pillars 104 (e.g., between the second slot region 124 and the first slot regions 122), without an additional portion of the isolation region 120 being formed between the second slot region 124 and the second pillars 105. For ease of understanding the disclosure, boundaries of the isolation region 120, the first slot regions 122, the second slot region 124 of the electronic device 100 are depicted by way of dashed lines in FIGS. 1A through 1D and throughout the remaining description and the accompanying figures.

The electronic device 100 may include support structure regions 107 (e.g., regions designated for subsequently formed support structures) proximate to one or more of the first slot regions 122 and the second slot region 124. For example, the support structure regions 107 may be located between at least some of the first slot regions 122. The support structure regions 107 may horizontally neighbor one or more areas including the first pillars 104, although other configurations may be contemplated. The stack 102 (FIG. 1B), including the first slot regions 122 and the second slot region 124 thereof, is described in further detail below.

Referring to FIGS. 1B through 1D, the stack 102 (e.g., a preliminary stack structure) may be formed to include a vertically alternating (e.g., in the Z-direction) sequence of insulative structures 106 and additional insulative structures 108 arranged in tiers 110. Each of the tiers 110 may include at least one of the insulative structures 106 and at least one of the additional insulative structures 108 vertically adjacent to the insulative structure 106. For clarity and ease of understanding of the drawings and related description, FIGS. 1B through 1D show the stack 102 as including four (4) tiers 110 (e.g., a first tier 110a, a second tier 110b, a third tier 110c, a fourth tier 110d) of the insulative structures 106 and the additional insulative structures 108. However, the stack 102 may include a different quantity of tiers 110. For example, in additional embodiments, the stack 102 includes greater than four (4) tiers 110 (e.g., greater than or equal to about sixty-four (64) of the tiers 110, greater than or equal to about one hundred (100) of the tiers 110, greater than or equal to about one hundred twenty-eight (128) of the tiers 110, greater than or equal to about two hundred fifty-six (256) of the tiers 110) of the insulative structures 106 and the additional insulative structures 108.

The insulative structures 106 may be formed of and include, for example, at least one dielectric material, such as at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and MgOₓ). In some embodiments, the insulative structures 106 are formed of and include SiO₂.

The additional insulative structures 108 may be formed of and include an insulative material that is different than (e.g., has a different chemical composition than), and exhibits an etch selectivity with respect to, the insulative structures 106. The additional insulative structures 108 may be formed of and include at least one dielectric nitride material (e.g., SiN_{y}) or at least one oxynitride material (e.g., SiOₓN_{y}). In some embodiments, the additional insulative structures 108 are formed of and include Si₃N₄. The additional insulative structures 108 may function as sacrificial structures for the subsequent formation of conductive structures, as described in further detail below.

As shown in FIG. 1B, the electronic device 100 may further include a source tier 112 (e.g., a source level) underlying (e.g., in the Z-direction) the stack 102, and a base structure 114 underlying the source tier 112. The source tier 112 may be vertically interposed between the stack 102 and the base structure 114. The source tier 112 may include at least one source structure 116 (e.g., a source plate, at least one source line, such as a common source line (CSL)), and may, optionally, include at least one insulative material 118 adjacent to (e.g., on or over) the source structure 116. The insulative material 118, if present, may vertically intervene between the source structure 116 and the stack 102. Alternatively, a lowermost one of the insulative structures 106 may be adjacent to (e.g., directly on) the source structure 116, and the insulative material 118 may not be present.

The source structure 116 of the source tier 112 may be formed of and include at least one conductive material. In some embodiments, the source structure 116 is formed of and includes tungsten (W). In other embodiments, the source structure 116 is formed of and includes conductively doped polysilicon. In additional embodiments, the source structure 116 may be formed of and include a stack of at least two differing conductive materials.

The insulative material 118 of the source tier 112 may be formed of and include at least one other insulative material. A material composition of the insulative material 118 may be substantially the same as a material composition of the insulative structures 106 or the additional insulative structures 108 of the stack 102, or the material composition of the insulative material 118 may be different than the material compositions of the insulative structures 106 and the additional insulative structures 108. In some embodiments, a material composition of the insulative material 118 is substantially the same as a material composition of the insulative structures 106 (e.g., SiO₂).

The base structure 114 may include at least one logic region including devices and circuitry for controlling various operations of other components of the electronic device 100. By way of non-limiting example, the logic region of the base structure 114 may include one or more (e.g., each) of charge pumps (e.g., V_{CCP} charge pumps, V_{NEGWL} charge pumps, DVC2 charge pumps), delay-locked loop (DLL) circuitry (e.g., ring oscillators), drain supply voltage (V_{dd}) regulators, devices and circuitry for controlling column operations for arrays (e.g., arrays of vertical memory strings) to subsequently be formed within the electronic device 100, such as one or more (e.g., each) of decoders (e.g., column decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry), I/O devices (e.g., local I/O devices), memory test devices, array multiplexers (MUX), and error checking and correction (ECC) devices, and devices and circuitry for controlling row operations for arrays (e.g., arrays of vertical memory strings) within memory regions of the electronic device 100, such as one or more (e.g., each) of decoders (e.g., row decoders), drivers (e.g., word line (WL) drivers), repair circuitry (e.g., row repair circuitry), memory test devices, MUX, ECC devices, and self-refresh/wear leveling devices. In some embodiments, the logic region of the base structure 114 includes complementary metal-oxide-semiconductor (CMOS) circuitry. In some such embodiments, the base structure 114 may be characterized as having a “CMOS under Array” (“CuA”) configuration, wherein the CMOS circuitry of the logic region is at least partially (e.g., substantially) positioned within horizontal areas of memory array regions of the electronic device 100.

As shown in FIGS. 1B through 1D, the first slot regions 122 and the at least one second slot region 124 include locations designated for subsequent positions of slots to be formed to extend vertically (e.g., in the Z-direction) substantially through the stack 102. As described in further detail below, first slots to be formed in the first slot regions 122 (FIG. 1B) and at least one second slot to be formed in the second slot region 124 (FIGS. 1C and 1D) may individually be formed to extend vertically through the tiers 110 (e.g., the first tier 110a, the second tier 110b, the third tier 110c, the fourth tier 110d) of the insulative structures 106 and the additional insulative structures 108 and to terminate at or above the source structure 116. The opposing portions of the isolation region 120 may be adjacent to the second slot region 124 and be formed to extend vertically substantially completely through the tiers 110 of the stack 102 and to terminate at or above the source structure 116.

The first pillars 104 (FIGS. 1B and 1C) may be formed in an array region (e.g., a memory array region) and may be configured as memory pillars (e.g., cell pillars). In addition, the second pillars 105 (FIGS. 1C and 1D) may horizontally neighbor (e.g., in the Y-direction) the first pillars 104 within the array region, and may be configured as so-called “dummy pillars” that are not operably coupled to (e.g., electrically connected to) the source structure 116. The second pillars 105 may alleviate undesirable array edge effects within the array region. The second pillars 105 may be formed in openings extending vertically at least partially through the tiers 110 of the stack 102. The second pillars 105 may be formed in the stack 102 using conventional processes (e.g., conventional deposition processes) and conventional processing equipment. In other embodiments, at least some of the second pillars 105 are configured as memory pillars and/or some of the first pillars 104 are configured as dummy pillars.

The first pillars 104 may exhibit a substantially rectangular horizontal cross-sectional shape (e.g., a substantially square horizontal cross-sectional shape) as shown in the top-down view of FIG. 1A. However, the disclosure is not so limited. As a non-limiting example, in additional embodiments, the first pillars 104 may exhibit a substantially circular horizontal cross-sectional shape. In addition, a pitch between horizontally adjacent first pillars 104 may be within a range of from about 50 nm to about 200 nm, such as from about 50 nm to about 100 nm, from about 100 nm to about 150 nm, or from about 150 nm to about 200 nm. In some embodiments, a critical dimension (CD) of an individual first pillar 104 in a horizontal direction is within a range of from about 20 nm to about 200 nm, such as from about 20 nm to about 50 nm, from about 50 nm to about 100 nm, from about 100 nm to about 150 nm, or from about 150 nm to about 200 nm, for example. One of ordinary skill in the art will appreciate that the pitch between horizontally neighboring first pillars 104 and the critical dimension of an individual first pillar 104 may be smaller or larger than the stated ranges and may be selected to achieve desired performance objectives. The second pillars 105 may or may not be substantially similarly sized and spaced as the first pillars 104.

The first pillars 104 may be formed in openings extending vertically through the tiers 110 of the stack 102. As shown in FIG. 1B, the first pillars 104 may individually include a cell film 104a, and a fill material 104b surrounded by the cell film 104a. For example, the cell film 104a may include a cell material formed within the openings, and a channel material formed over the cell material. For convenience, the cell material and channel material are illustrated as a single material (e.g., the cell film 104a) in FIG. 1B. However, the cell film 104a may include both the cell material and the channel material. The cell material and channel material may be formed by conventional techniques, such as by CVD or ALD. The cell material may, for example, be an oxide-nitride-oxide (ONO) material, such as a silicon oxide-silicon nitride-silicon oxide material, that is conformally formed over sidewalls of the fill material 104b. The cell material may be formed at a smaller relative thickness than the channel material. The channel material may be conformally formed over the cell material. The channel material may, for example, comprise a semiconductor material, such as polysilicon. The fill material 104b may be formed over the channel material of the cell film 104a and may fill (e.g., substantially fill) remainders (e.g., unfilled portions) of the openings. The fill material 104b may be an insulative material, such as an oxide dielectric material (e.g., SiO₂). The fill material 104b may be substantially uniform and substantially conformal as deposited. The fill material 104b may be formed by conventional techniques, such as by ALD. In some embodiments, the fill material 104b is an ALD SiOₓ. The fill material 104b may initially be formed in the openings and over exposed horizontal surfaces of the tiers 110, with the fill material 104b over the tiers 110 subsequently removed, such as by an abrasive planarization process (e.g., chemical mechanical planarization (CMP)). Accordingly, the fill material 104b may be surrounded by the cell material and the channel material of the cell film 104a. In additional embodiments, the fill material 104b may, optionally, include an interior void (e.g., hollow portion, air gap). The cell film 104a of the first pillars 104 may be operably associated with the source structure 116 underlying the stack 102.

The support structure regions 107 of subsequently formed support structures may be horizontally proximate to one or more areas including the first pillars 104. The support structure regions 107 may, for example, be horizontally proximate to the first slot regions 122 and the second slot region 124, in regions outside of areas including the first pillars 104 and the second pillars 105. In some embodiments, the first slot regions 122 and the second slot region 124 may be confined within the array region. In other embodiments, at least portions of the second slot region 124 extend beyond a horizontal area of the array region.

Referring to FIG. 2A, first slots 126 (e.g., trenches, openings) and at least one second slot 128 (e.g., at least one additional trench, at least one additional opening) may be formed to extend vertically into the portions of the stack 102 (FIG. 2B). In addition, openings 117 (e.g., support structure openings) may be formed to extend vertically into the portions of the stack 102 between at least some of the first slots 126. The first slots 126, the second slot 128, and the openings 117 may be formed by removing portions of the materials (e.g., the insulative structures 106, the additional insulative structures 108) of the stack 102. In some embodiments, additional portions of the materials of the stack 102 may remain within the isolation region 120. FIGS. 2B, 2C, 2D, and 2E are simplified cross-sectional views of the electronic device 100 taken along the B-B line, the C-C line, the D-D line, and the E-E line, respectively, of FIG. 2A.

The second slot 128 may extend in the first horizontal direction (e.g., the X-direction), and each of the first slots 126 may extend in the second horizontal direction (e.g., the Y-direction) transverse to the first horizontal direction. The opposing portions of the isolation region 120 may extend in the first horizontal direction and adjacent to elongated sides of the second slot 128. In some embodiments, the first slots 126 may initially be formed to intersect the second slot 128 at intersections 130 within a horizontal area of intersection regions 136 (e.g., regions of the stack 102 including the initially formed intersections 130), as shown for one of the second slots 128 on the right-hand side of FIG. 2A and illustrated in the cross-sectional view of FIG. 2E. The intersections 130 may be defined as locations at which the second slot 128 extending in the first horizontal direction and the first slots 126 extending in the second horizontal direction meet. The intersections 130 may be contained within a cross-sectional area the intersection regions 136 and be defined by internal sidewalls of the materials of the stack 102, without including portions of the materials of the stack 102. The intersection regions 136 may at least partially surround the intersections 130 and may include portions of the materials of the stack 102 adjacent to the first slots 126 and the second slot 128. Subsequently formed isolation structures of the isolation region 120 may facilitate desired horizontal spacing (e.g., in the Y-direction) between the first slots 126 and the second slot 128. While the first slots 126 initially intersect the second slot 128 at the intersections 130, in some embodiments, the first slots 126 may be separated from (e.g., isolated from) the second slot 128 within the intersection regions 136 following subsequent processing acts, as described in further detail below.

In other embodiments, end portions of at least some (e.g., each) of the first slots 126 are formed proximal to the second slot 128 within the intersection regions 136, without intersecting (e.g., meeting) the second slot 128 at the intersections 130. For example, remaining portions of the tiers 110 (FIG. 2B) of the stack 102 (FIG. 2B) may laterally intervene between the first slots 126 and the second slot 128 within the isolation region 120, as shown for the remaining first slots 126 on the left-hand side of FIG. 2A and illustrated in the cross-sectional view of FIG. 2D. In other words, the first slots 126 and the second slot 128 may initially be formed to be proximal one another within the intersection regions 136, and remaining portions of the materials (e.g., the insulative structures 106, the additional insulative structures 108) of the stack 102 may separate the first slots 126 from the second slot 128. Accordingly, portions of the materials of the stack 102 may, optionally, remain in the isolation region 120 between at least some (e.g., each) of the first slots 126 and the second slot 128, as shown for clarity and convenience throughout the remaining description and the accompanying figures.

As shown in FIG. 2A, the first slots 126 may be formed within the first slot regions 122 (FIG. 1A) and the second slot 128 may be formed within the at least one second slot region 124 (FIG. 1A). The first slots 126 and the second slot 128 may each be formed to extend vertically substantially completely through the stack 102. As shown in FIG. 2B, each of the first slots 126 may extend vertically (e.g., in the Z-direction) from a vertically uppermost boundary of the stack 102 to an upper surface of the source structure 116 underlying the stack 102. In addition, the second slot 128 may extend vertically through the tiers 110 of the stack 102, as shown in FIGS. 2C through 2E. While FIG. 2A illustrates a single (e.g., only one) second slot 128 within a single second slot region 124 proximate a perimeter (e.g., outer horizontal boundaries) of the stack 102, additional configurations may be contemplated. For example, the single second slot 128 may be centrally located within the stack 102 in the second horizontal direction (e.g., the Y-direction) and relatively remote from the perimeter of the stack 102. In additional embodiments, multiple (e.g., two or more) second slots 128 may be formed horizontally proximate one another in the second horizontal direction.

The first slots 126 may or may not be formed substantially simultaneously with formation of the second slot 128. In some embodiments, the first slots 126 and the second slot 128 may be formed using a single material removal act. However, additional material removal processes may be contemplated. For example, the first slots 126 may be formed before or after formation of the second slot 128. In additional embodiments, one or more of the first slots 126 and the second slot 128 may be formed during additional material removal processes used to form additional features (e.g., openings, structures) that extend vertically substantially completely through the stack 102. Such features may include, for example, pillars, staircase structures, etc.

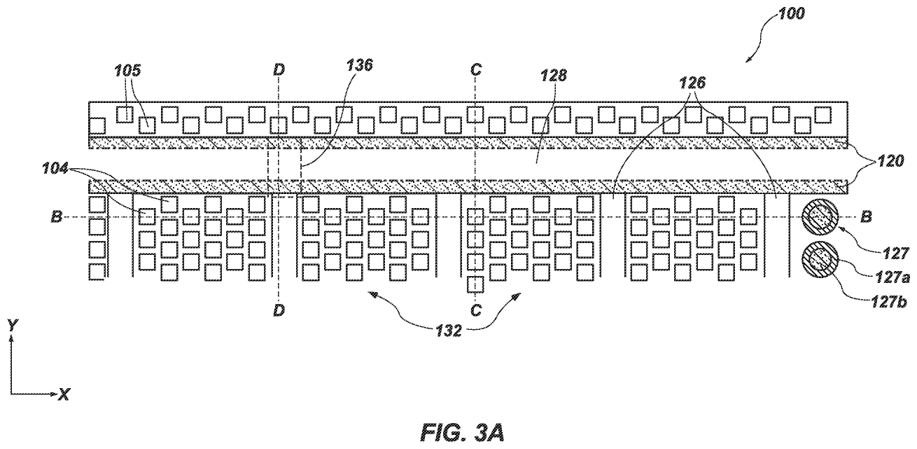

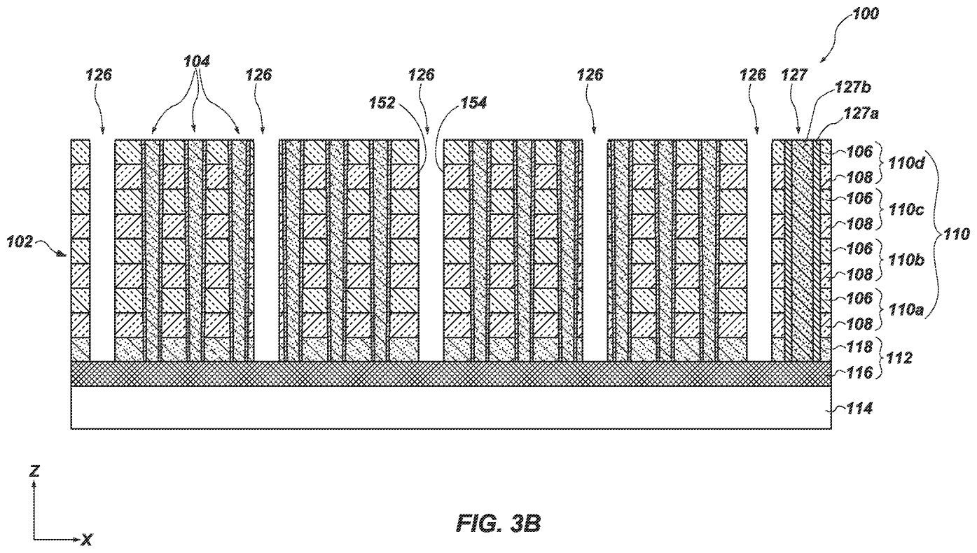

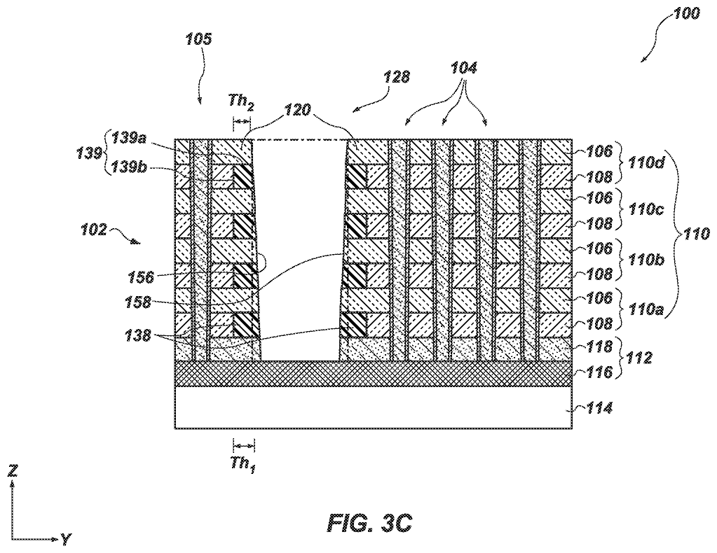

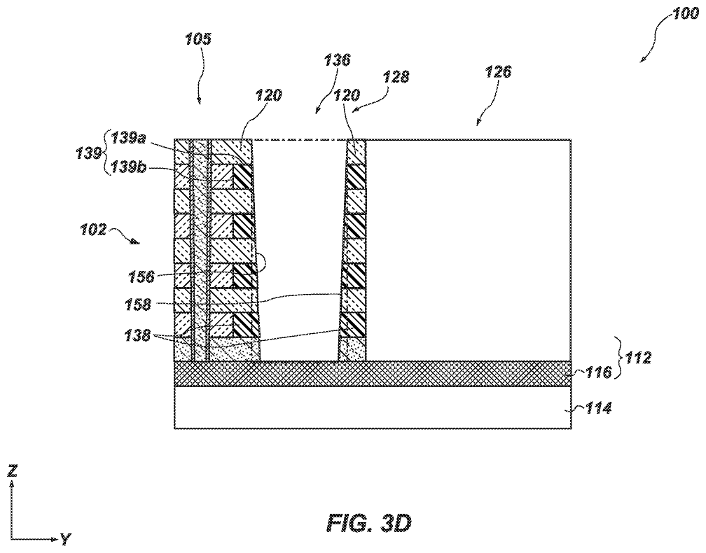

The openings 117 may be formed within the support structure regions 107 (FIG. 1A) and may be proximate to one or more of the first slots 126 and the second slot 128. The openings 117 extend vertically substantially completely through the stack 102 and exhibit a height substantially similar to (e.g., the same as) a height of the first slots 126. The openings 117 may be formed during the same material removal act used to form one or more of the first slots 126 and the second slot 128 or, alternatively, using one or more additional material removal acts. For example, the openings 117 may be formed during formation of the second slot 128 using a single (e.g., one) masking act to reduce cost and the number of process acts conducted. In additional embodiments, the support structures 127 (see FIG. 3A) may be formed in the openings 117 prior to formation of one or more of the first slots 126 and the second slot 128.

The openings 117 may have any suitable transverse cross-sectional shape such as, for example, a substantially circular cross-sectional shape, a substantially square cross-sectional shape, or a substantially elliptical cross-sectional shape. The cross-sectional shape of support structures 127 (see FIG. 3A) subsequently formed in the openings 117 may be tailored to provide sufficient mechanical support to the electronic device 100 without conductivity loss of the electronic device 100. In some embodiments, each of the openings 117 may individually exhibit a substantially circular cross-sectional shape having a substantially circular cross-sectional area. A lateral dimension (e.g., a diameter) of the openings 117 may be relatively larger than a lateral dimension (e.g., a width) of the first slots 126. While two openings 117 are shown in FIG. 2A for clarity, any number of the openings 117 may be formed laterally adjacent to the first slots 126.

The first slots 126 may individually have a first width W₁ (e.g., a horizontal dimension) in the X-direction, and the second slot 128 may have a second width W₂ (e.g., a horizontal dimension) in the Y-direction taken at a vertically uppermost boundary of the stack 102. In some embodiments, the second width W₂ of the second slot 128 is relatively larger than the first width W₁ of the first slots 126. In additional embodiments, the second width W₂ is substantially the same as (e.g., substantially equal to) the first width W₁ or, alternatively, the second width W₂ is relatively smaller than the first width W₁. The relative widths of the slots may be tailored to have a desired value that may be selected at least partially based on design requirements of the electronic device 100. By way of non-limiting example, the first width W₁ of the first slots 126 may be within a range from about 100 nm to about 400 nm, such as from about 100 nm to about 200 nm, from about 200 nm to about 300 nm, or from about 300 nm to about 400 nm. The first width W₁ of the first slots 126 may be substantially uniform (e.g., constant, non-variable) across a height of the stack 102 or, alternatively, the first slots 126 may exhibit a tapered profile with an upper portion of individual first slots 126 having a greater critical dimension (e.g., width) than a lower portion thereof. Sidewalls of the stack 102 defining the first slots 126 may be substantially linear in the Z-direction.

The second width W₂ of the second slot 128 may be within a range from about 100 nm to about 600 nm, such as from about 100 nm to about 200 nm, from about 200 nm to about 300 nm, from about 300 nm to about 400 nm, from about 400 nm to about 500 nm, or from about 500 nm to about 600 nm. The second width W₂ of the second slot 128 may be substantially uniform across a height of the stack 102 or, alternatively, the second slot 128 may exhibit a tapered profile with an upper portion of the second slot 128 having a greater critical dimension (e.g., width) than a lower portion thereof. Sidewalls of the stack 102 defining the second slot 128 may be substantially linear in the Z-direction. Further, a critical dimension (e.g., width) of the openings 117 may be substantially the same as (e.g., substantially equal to) the second width W₂ of the second slot 128, such as when the openings 117 are formed during formation of the second slot 128.

As shown in FIG. 2A, the isolation region 120 including the materials of the stack 102 may have a third width W₃ (e.g., a horizontal dimension) in the Y-direction that is relatively greater than the second width W₂ of the second slot 128. For example, an outer boundary of the isolation region 120 may be relatively wider than an outer boundary of the second slot 128 in the Y-direction. Accordingly, outer boundaries of the opposing portions of the isolation region 120 may extend beyond outer boundaries of the second slot 128 by a distance D₁ taken at a vertically lowermost boundary of the stack 102 (see FIG. 2C). By way of non-limiting example, the distance D₁, may be within a range from about 200 nm to about 600 nm, such as from about 200 nm to about 300 nm, from about 300 nm to about 400 nm, from about 400 nm to about 500 nm, or from about 500 nm to about 600 nm, although other configurations may be contemplated. In some embodiments, the third width W₃ of the isolation region 120 is selected to facilitate a desired horizontal distance between the second slot 128 and each of the first pillars 104 and the second pillars 105, and to facilitate desired horizontal spacing (e.g., in the Y-direction) between the first slots 126 and the second slot 128, upon separation of the slots. Further, the third width W₃ of the isolation region 120 may be selected to accommodate formation of isolation structures 138 (see FIGS. 3C and 3D) between the first slots 126 and the second slot 128, as described in further detail below. The third width W₃ may, for example, be within a range of from about 200 percent to about 500 percent (e.g., from about 200 percent to about 300 percent, from about 300 percent to about 400 percent, from about 400 percent to about 500 percent) larger than the second width W₂. The third width W₃ may be between about 2 and 10 times (e.g., an order of magnitude) greater than the second width W₂. By way of non-limiting example, the second width W₂ may be within a range from about 400 nm to about 600 nm (e.g., about 500 nm) and the third width W₃ may be within a range from about 500 nm (e.g., 0.5 micrometers (μm)) to about 6000 nm (e.g., 6 μm). For example, the third width W₃ may be within a range from about 0.5 μm to about 2 μm, from 2 μm to about 4 μm, from about 4 μm to about 6 μm, or even larger, depending on design requirements of the electronic device 100.

As shown in FIG. 2A, the first slots 126 and the second slot 128 may divide the stack 102 into multiple blocks 132. The blocks 132 may each extend in substantially the same horizontal direction (e.g., the Y-direction) as one another, and neighboring blocks 132 may be horizontally separated (e.g., in the X-direction) from one another by the first slots 126. Each of the blocks 132 may exhibit substantially the same geometric configuration (e.g., dimensions, shape) as each other of the blocks 132 of the array. In addition, horizontally neighboring blocks 132 may all be horizontally separated from one another by substantially the same distance (e.g., corresponding to the first width W₁ of the first slots 126). Accordingly, the blocks 132 may be substantially uniformly (e.g., non-variably, equally, consistently) sized, shaped, and spaced relative to one another.

As shown in FIG. 2B, the first slots 126 may comprise substantially linear, elongated openings having one end at the vertically uppermost boundary of a vertically uppermost tier 110 of the stack 102 and another end at the upper surface of the source structure 116. The first slots 126 may individually be defined by sidewalls 152, 154 (e.g., vertical and internal sidewalls) of the materials (e.g., the insulative structures 106, the additional insulative structures 108) of the stack 102. In particular, the internal sidewalls 152, 154 may be substantially linear and extend vertically upward from the upper surface of the source structure 116 to the vertically uppermost boundary of the vertically uppermost tier 110 (e.g., the fourth tier 110d) of the stack 102. The first slots 126 may be formed in the stack 102 using conventional material removal (e.g., masking and etching) processes. For example, one or more portions of the stack 102 may be subjected to at least one etching process (e.g., at least one dry etching process, such as one or more of a reactive ion etching (RIE) process, a deep RIE process, a plasma etching process, a reactive ion beam etching process, and a chemically assisted ion beam etching process, at least one wet etching process, such as one or more of a hydrofluoric acid etching process, a buffered hydrofluoric acid etching process, and a buffered oxide etching process) to form the first slots 126 in the stack 102.

As shown in FIGS. 2C through 2E, the second slot 128 may comprise substantially linear, elongated openings having one end at the vertically uppermost boundary of a vertically uppermost tier 110 of the stack 102 and another end at the upper surface of the source structure 116. The second slot 128 may be defined by sidewalls 156, 158 (e.g., vertical and internal sidewalls) of the materials of the stack 102. In particular, the internal sidewalls 156, 158 may initially be formed to be substantially linear and extend vertically upward from the upper surface of the source structure 116 to the vertically uppermost boundary of the vertically uppermost tier 110 (e.g., the fourth tier 110d) of the stack 102. The second slot 128 may be formed in the stack 102 using conventional material removal (e.g., masking and etching) processes, similar to processes used to form the first slots 126. In embodiments including the second slot 128 exhibiting a tapered profile with an upper portion of the second slot 128 having a greater critical dimension (e.g., width) than a lower portion thereof, the distance D 1 of the opposing portions of the isolation region 120 taken at a vertically lowermost boundary of the stack 102 (e.g., the first tier 110a) may be relatively greater than that taken at a vertically uppermost boundary of the stack 102 (e.g., the fourth tier 110d).

Following formation of the second slot 128, lateral (e.g., in the X-direction, in the Y-direction) portions of the additional insulative structures 108 may be selectively removed through the second slot 128 to form separation regions 134 (e.g., recessed regions). By way of non-limiting example, exposed portions of the additional insulative structures 108 may be exposed to a so-called “wet nitride strip” (e.g., a first wet nitride strip) comprising a wet etchant through the second slot 128 to selectively remove portions of the additional insulative structures 108 with respect to the insulative structures 106. In some embodiments, the additional insulative structures 108 are exposed to phosphoric acid (H₃PO₄) to selectively remove portions of the additional insulative structures 108 proximate the second slot 128. The separation regions 134 may be formed by recessing end portions of the additional insulative structures 108 through the second slot 128, without recessing end portions of the insulative structures 106 adjacent to the second slot 128. Accordingly, end surfaces of the additional insulative structures 108 of the stack 102 adjacent to the second slot 128 are horizontally recessed relative to end surfaces of the insulative structures 106 within the isolation region 120.

As shown in FIG. 2C, a horizontal dimension of the separation regions 134 corresponds to the distance D₁ of the opposing portions of the isolation region 120. In other words, the separation regions 134 are formed within the opposing portions of the isolation region 120 and external to (e.g., outside of) a horizontal area of the second slot 128 defined by the internal sidewalls 156, 158. The separation regions 134 horizontally overlap ends of the first slots 126 within the isolation region 120, such that the separation regions 134 extend some distance beyond the ends of the first slots 126. While FIGS. 2A through 2E illustrate the first slots 126 (FIG. 2B) being formed prior to formation of the separation regions 134 for clarity, the disclosure is not so limited, and the first slots 126 may be formed following formation of the separation regions 134.

As shown in FIG. 2D, remaining portions of the tiers 110 (FIG. 2B) of the stack 102 may laterally intervene between the first slots 126 and the second slot 128 within the isolation region 120, in some embodiments. As discussed above, at least some (e.g., each) of the first slots 126 and the second slot 128 may initially be formed to be proximal one another within the intersection regions 136 without intersecting one another, and remaining portions of the materials (e.g., the insulative structures 106 (FIG. 2C), the additional insulative structures 108 (FIG. 2C)) of the stack 102 may initially separate the first slots 126 from the second slot 128. The separation regions 134 may be formed within the opposing portions of the isolation region 120 within regions previously occupied by the additional insulative structures 108. Accordingly, portions of the materials (e.g., the insulative structures 106) of the stack 102 may be present in the isolation region 120 between at least some (e.g., each) of the first slots 126 and the second slot 128.

As shown in FIG. 2E, the first slots 126 may initially be formed to intersect the second slot 128 at the intersections 130 and within a horizontal area of the intersection regions 136, in other embodiments. Subsequently formed isolation structures of the isolation region 120 may facilitate desired horizontal spacing (e.g., in the Y-direction) between the first slots 126 and the second slot 128. Accordingly, the isolation region 120 may not be present between the first slots 126 and the second slot 128. While the first slots 126 initially intersect the second slot 128 at the intersections 130, in some embodiments, the first slots 126 may be separated from (e.g., isolated from) the second slot 128 within the intersection regions 136 following subsequent processing acts, as described in further detail below with reference to FIG. 3D. In addition, while FIGS. 2A and 2E illustrate one of the first slots 126 initially intersecting the second slot 128 for clarity, the disclosure is not so limited, and portions of the materials of the stack 102 may remain in the isolation region 120 between at least some (e.g., each) of the first slots 126 and the second slot 128, as discussed above with reference to FIG. 2D.

Referring to FIG. 3A in combination with FIGS. 3B through 3D, the isolation structures 138 (FIGS. 3C and 3D) may be formed within the separation regions 134 (FIGS. 2C and 2D) of the isolation region 120 on one or more (e.g., two opposing) sides of the second slot 128. The isolation structures 138 may at least partially (e.g., substantially) fill the separation regions 134. In addition, the support structures 127 (e.g., mechanical support pillars) may be formed within the openings 117 (FIG. 2A) between at least some of the first slots 126, as shown in FIG. 3A. In some embodiments, a material composition of one or more materials of the support structures 127 may be substantially the same as a material composition of the isolation structures 138. FIGS. 3B, 3C, and 3D are simplified cross-sectional views of the electronic device 100 taken along the B-B line, the C-C line, and the D-D line, respectively, of FIG. 3A.

Referring collectively to FIGS. 3A through 3D, after selectively removing portions of the additional insulative structures 108 proximate the second slot 128, one or more dielectric materials (e.g., barrier material) may be formed within the separation regions 134 (FIGS. 2C and 2D) proximate remaining portions of the additional insulative structures 108 to form the isolation structures 138. For example, the isolation structures 138 may be formed within the separation regions 134 adjacent to the second slot 128. The isolation structures 138 may be formed to extend between vertically neighboring insulative structures 106 proximate the second slot 128, such that the isolation structures 138 substantially vertically fill the separation regions 134. In other words, the isolation structures 138 may substantially fill the separation regions 134 and may be in contact with each of the insulative structures 106 and the additional insulative structures 108 of the stack 102. Accordingly, the isolation structures 138 may be formed to extend from upper surfaces of the insulative structures 106 to lower surfaces of vertically neighboring insulative structures 106. The isolation structures 138 may be formed by conventional techniques, such as one or more of in situ growth, CVD, ALD, and PVD using conventional processing equipment. In some embodiments, the isolation structures 138 may be formed (e.g., deposited) using a single, continuous ALD process or a single, continuous CVD process. In other embodiments, an initial material (e.g., a silicon nitride material of the additional insulative structures 108) may be oxidized to form the isolation structures 138.

The isolation structures 138 may comprise one or more of the materials described above with reference to the insulative structures 106. In some embodiments, a material of the isolation structures 138 comprises SiO₂. The isolation structures 138 may be formed of and include at least one insulative material that is different than, and that exhibits etch selectivity with respect to, the additional insulative structures 108. In some embodiments, the isolation structures 138 are formed of and includes a single high quality (e.g., highly conformal) silicon oxide material, such as an ALD SiOₓ. For example, a material of the isolation structures 138 may be a highly uniform and highly conformal silicon oxide material (e.g., a highly uniform and highly conformal silicon dioxide material) so that substantially no voids are present in the isolation structures 138. The isolation structures 138 may, alternatively, be formed of and include one or more of silicon oxycarbide (SiOₓC_{y}), silicon oxynitride (SiOₓN_{y}), hydrogenated silicon oxycarbide (SiCₓO_{y}H_{z}), or silicon oxycarbonitride (SiOₓC_{y}N_{z}). The isolation structures 138 may include a low-k dielectric material, such as a dielectric nitride material or a dielectric oxide material, having a dielectric constant (k) lower than the dielectric constant of a silicon nitride (Si₃N₄) material, of a silicon oxide (SiOₓ, SiO₂) material, or of a carbon-doped silicon oxide material that includes silicon atoms, carbon atoms, oxygen atoms, and hydrogen atoms.

The isolation structures 138 may be between the second slot 128 and the additional insulative structures 108, such that the additional insulative structures 108 are remote (e.g., isolated) from the second slot 128 by the isolation structures 138. The isolation structures 138 may also be between the second slot 128 and the first slots 126, such that the first slots 126 are remote (e.g., isolated) from the second slot 128 by the isolation structures 138. Stated another way, process acts may be selected to provide (e.g., facilitate, promote) formation of the material within the separation regions 134 (FIGS. 2C and 2D) proximate the second slot 128 for formation of the isolation structures 138 between the horizontally neighboring additional insulative structures 108 and subsequently formed materials (e.g., an additional dielectric material) within the second slot 128 and between portions of subsequently formed materials (e.g., the additional dielectric material) within the first slots 126. After forming the isolation structures 138, the electronic device 100 may be exposed to one or more material removal processes to remove portions of the material of the isolation structures 138 within and outside of the second slot 128.

As shown in FIGS. 3C and 3D, the isolation structures 138 may contact surrounding materials along interfaces 139. For example, one or more surfaces (e.g., upper surfaces, lower surfaces) of at least some of the isolation structures 138 may directly contact surfaces (e.g., lower surfaces, upper surfaces) of the insulative structures 106 along interfaces 139a (e.g., horizontal interfaces). Further, one or more side surfaces (e.g., lateral side surfaces, horizontal side surfaces) of individual isolation structures 138 may directly contact side surfaces of the additional insulative structures 108 of the stack 102 along an interface 139b (e.g., a vertical interface). The interface 139b may extend in a direction substantially parallel to a longitudinal axis of the first pillars 104 and substantially transverse to a major surface of the source tier 112. In embodiments including remaining portions of the materials of the stack 102 separating the first slots 126 from the second slot 128, the isolation structures 138 may be formed within each of the opposing portions of the isolation region 120, as shown in FIG. 3D. In other words, each opposing portion of the isolation region 120 may include segmented portions of the isolation structures 138 vertically intervening between the insulative structures 106 of the tiers 110. In embodiments including the first slots 126 initially formed to intersect the second slot 128, one or more materials (e.g., a continuous portion of the material of the isolation structures 138) may, optionally, be formed in the isolation region 120 between the first slots 126 and the second slot 128.

For example, in embodiments including the first slots 126 initially formed to intersect the second slot 128 at the intersections 130 (FIG. 2A), the isolation region 120 may include one or more materials (e.g., dielectric material, barrier material) extending vertically through the stack 102 (e.g., from the upper surface of the source structure 116 to the vertically uppermost boundary of the vertically uppermost tier 110 (e.g., the fourth tier (110d) of the stack 102). In other words, portions of the materials of the stack 102 within the isolation region 120 removed during initial formation of the first slots 126 and the second slot 128 at the intersections 130 are thereafter replaced with the one or more materials to separate the first slots 126 from the second slot 128, so long as conductive structures (e.g., access lines of neighboring blocks 132 are isolated from one another.

Since the isolation structures 138 are formed within the opposing portions of the isolation region 120, thicknesses of the isolation structures 138 correspond to the distance D₁ (FIG. 2C) of the opposing portions of the isolation region 120. In some embodiments, the isolation structures 138 exhibit thicknesses (e.g., in the Y-direction) that are substantially the same as (e.g., substantially equal to) one another. In embodiments including the second slot 128 exhibiting a tapered profile, the isolation structures 138 proximate the vertically lowermost boundary of the stack 102 (e.g., the first tier 110a) may exhibit a first thickness Th₁ that is relatively greater than a second thickness Th₂ of the isolation structures 138 proximate the vertically uppermost boundary of the stack 102 (e.g., the fourth tier 110d), as shown in FIG. 3C. In other words, the isolation structures 138 of the vertically lowermost tier 110 may exhibit a thickness in the Y-direction that is relatively greater than a thickness of the isolation structures 138 of the vertically uppermost tier 110.

Accordingly, the isolation structures 138 are located external to (e.g., outside of) horizontal areas of the second slot 128 and horizontally overlapping ends of the first slots 126, such that the isolation structures 138 extend beyond the ends of the first slots 126. Segmented portions of the isolation structures 138 may be laterally adjacent to the additional insulative structures 108 of the stack 102 and vertically adjacent to the insulative structures 106 of the stack 102. In other words, the isolation structures 138 vertically intervene between vertically neighboring insulative structures 106, as shown in FIG. 3D. In other embodiments, at least one of the opposing portions of the isolation region 120 comprises one or more materials between the first slots 126 and the second slot 128 following subsequent processing acts, as described in further detail below.

As shown in FIG. 3A in combination with FIG. 3B, the support structures 127 may be formed to provide additional mechanical integrity and support to portions of the tiers 110 of the insulative structures 106 and the additional insulative structures 108. In some embodiments, the support structures 127 are positioned within or proximate to regions of the stack 102 prone to tier collapse during subsequent processing acts (e.g., subsequent material removal acts). In some embodiments, the support structures 127 are positioned horizontally proximate to one or more areas designated for the first pillars 104. In other embodiments, the support structures 127 are positioned horizontally proximate to the first slots 126 and the second slot 128, in regions outside of boundaries of regions designated for one or more of the first pillars 104 and the second pillars 105. In some such embodiments, the electronic device 100 may include the support structures 127 between horizontally neighboring portions of the first slots 126 that are substantially absent (e.g., substantially devoid) of the first pillars 104 and the second pillars 105.

The support structures 127 may be formed in the openings 117 (FIG. 2A) extending vertically through the tiers 110 of the stack 102. The support structures 127 may include one or more materials. For example, the support structures 127 may individually include a liner 127a, and a fill material 127b surrounded by the liner 127a. For each of the support structures 127, the liner 127a may be formed (e.g., conformally formed) within the openings 117 (FIG. 2A) formed in the stack 102. The liner 127a may be continuous along a vertical distance of the stack 102. The liner 127a may be formed of and include insulative material, such as a dielectric oxide material. For example, the material of the liner 127a may include a silicon oxide material (e.g., relatively high quality silicon oxide material, such as an ALD SiOₓ). A material composition of the liner 127a may be substantially the same as a material composition of one or more of the isolation structures 138 and the insulative structures 106 of the stack 102, or the material composition of the liner 127a may be different than the material compositions of the isolation structures 138 and the insulative structures 106. In some embodiments, a material composition of the liner 127a is substantially the same as a material composition of the isolation structures 138 (SiO₂). The liner 127a may or may not be formed substantially simultaneously with formation of the isolation structures 138. The material of the liner 127a may exhibit etch selectivity with respect to the additional insulative structures 108. The liner 127a may be formed by conventional techniques, such as by CVD or ALD. In some embodiments, the liner 127a is formed by plasma enhanced ALD (PEALD).

The fill material 127b of the support structures 127 may be formed adjacent (e.g., over) the liner 127a. In some embodiments, the fill material 127b is formed of and includes an insulative material, such as a silicon oxide material. In other embodiments, the fill material 127b is formed of and includes a conductive material including, but not limited to, n-doped polysilicon, p-doped polysilicon, undoped polysilicon, or a metal, such as tungsten. The liner 127a may substantially surround sidewalls of the fill material 127b. In some embodiments, such as where the fill material 127b comprises an insulative material, the support structures 127 may not include the liner 127a on sidewalls of the fill material 127b, and the support structures 127 may only include the fill material 127b (e.g., the insulative material).

The fill material 127b of the support structures 127 may be formed to substantially fill remaining portions of the openings 117 (FIG. 2A) extending vertically through the stack 102 and to the source tier 112. The support structures 127 may be proximate to one or more of the first slots 126 and the second slot 128. At least some of the support structures 127 may be formed to extend vertically from the vertically uppermost surface of the stack 102 to the upper surface of the source structure 116. Alternatively or additionally, at least some of the support structures 127 (e.g., including the conductive material as the fill material 127b) may be formed to extend below the upper surface of the source structure 116, into the source structure 116. In some embodiments, the support structures 127 are configured to provide one or more functions (e.g., electrical connections) in addition to support functions. In additional embodiments, the support structures 127 are configured to substantially only provide support functions. Upper surfaces of each of an uppermost one of the insulative structures 106 of the tiers 110 (e.g., the fourth tier 110d) of the stack 102, the first pillars 104, and the support structures 127 may be substantially coplanar with one another.

The support structures 127 may individually exhibit a substantially circular cross-sectional shape, as shown in the top-down view of FIG. 3A. However, the disclosure is not so limited. As a non-limiting example, in additional embodiments, the support structures 127 individually exhibit a substantially rectangular cross-sectional shape (e.g., a substantially square cross-sectional shape), or a different elongate cross-sectional shape (e.g., an oblong cross-sectional shape). A lateral dimension (e.g., a width, a diameter in a horizontal direction) of one or more of the support structures 127 may be relatively larger than a lateral dimension of one or more (e.g., each) of the first pillars 104 and the second pillars 105.

In some embodiments, one or more materials of the support structures 127 may be formed during formation of the isolation structures 138. For example, the liner 127a of the support structures 127 may be formed at substantially the same time as the isolation structures 138, and the fill material 127b thereof may be formed following formation of the liner 127a and the isolation structures 138. By forming the liner 127a of the support structures 127 during formation of the isolation structures 138, manufacturing costs may be reduced. However, additional processes may be contemplated. For example, the support structures 127, including the liner 127a and the fill material 127b, may be formed before or, alternatively, after formation of the isolation structures 138. While FIG. 3A illustrates the support structures 127 being formed following formation of the first slots 126 and the second slot 128 for clarity, the disclosure is not so limited, and the support structures 127 and be formed prior to formation one or more of the first slots 126 and the second slot 128 and prior to formation of the isolation structures 138.

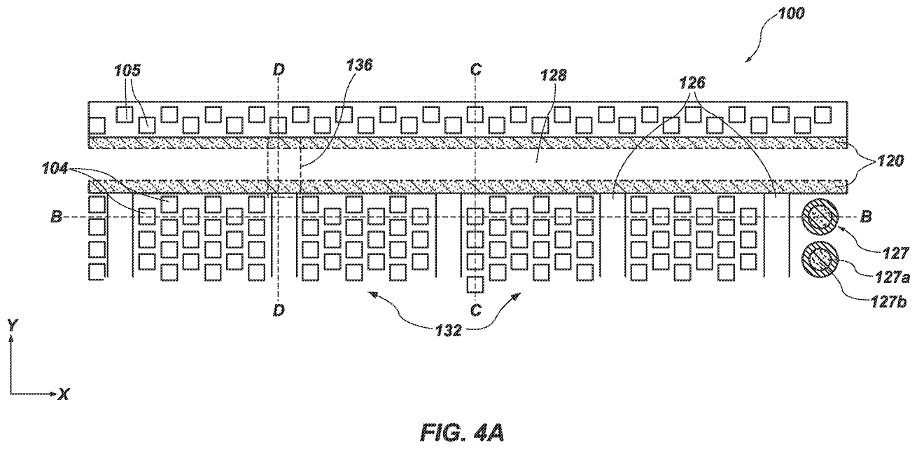

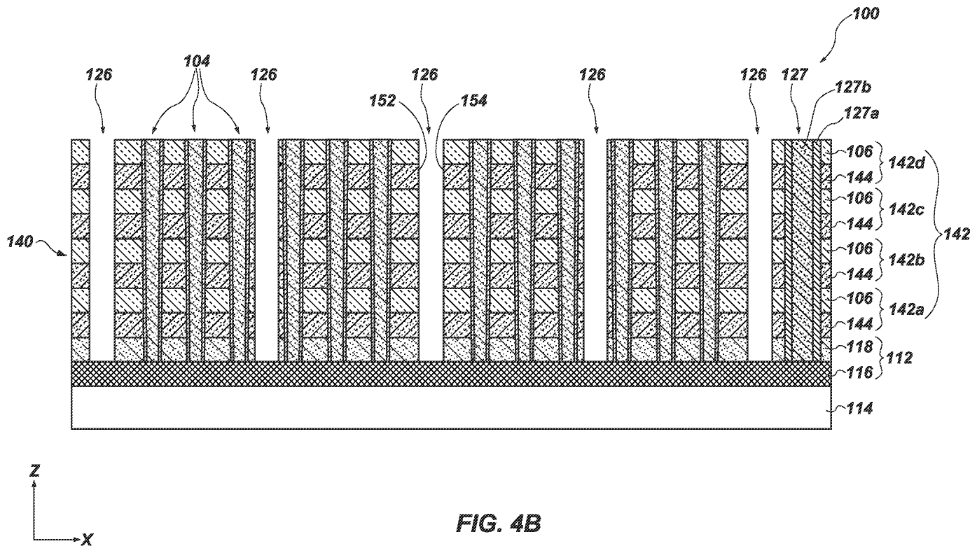

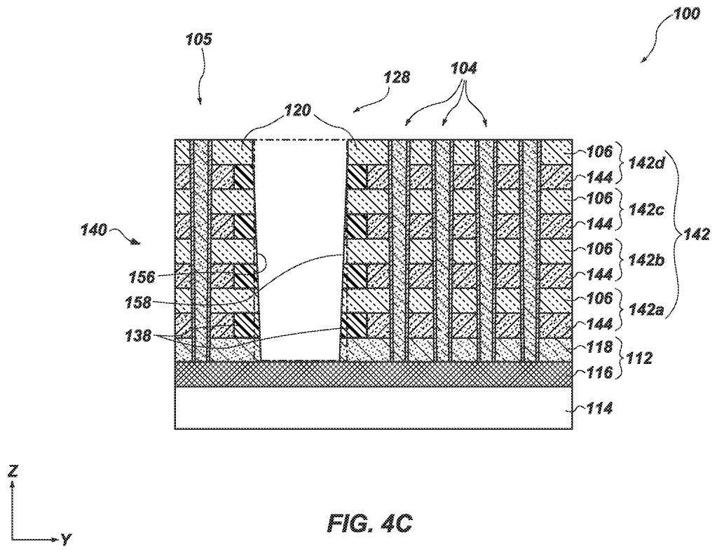

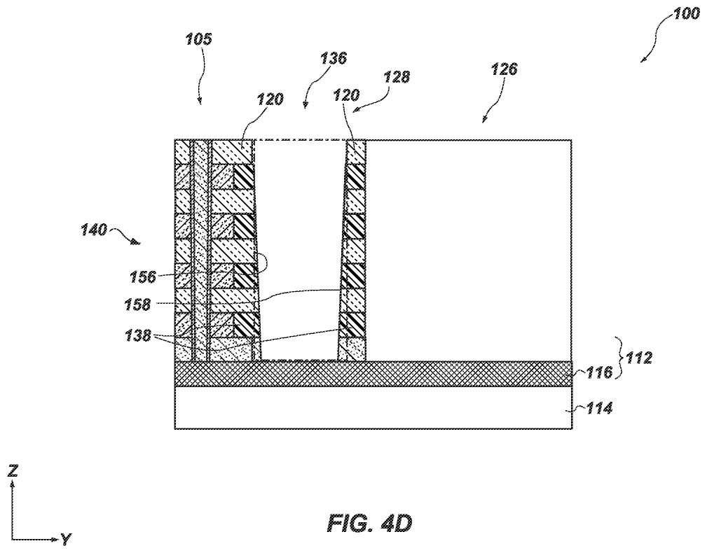

Referring to FIG. 4A, the electronic device 100 at the processing stage depicted in FIGS. 3A through 3D may be subjected to a “replacement gate” or “gate last” process to convert the stack 102 (FIG. 3B) into a stack 140 (FIGS. 4B through 4D). FIGS. 4B, 4C, and 4D are simplified cross-sectional views of the electronic device 100 taken along the B-B line, the C-C line, and the D-D line, respectively, of FIG. 4A.

Referring to FIGS. 4A through 4D, the replacement gate process may include selectively removing portions of the additional insulative structures 108 (FIG. 3B) of the tiers 110 (FIG. 3B) of the stack 102 (FIG. 3B) exposed by one or more of the first slots 126 and the second slot 128, and then filling spaces previously occupied by the portions of the additional insulative structures 108 with at least one conductive material to form conductive structures 144. As shown in FIG. 4B, the stack 140 may be formed to include a vertically alternating (e.g., in the Z-direction) sequence of the insulative structures 106 and the conductive structures 144 arranged in tiers 142. A quantity of the tiers 142 in the stack 140 may correspond to (e.g., be the same as) the quantity of the tiers 110 included in the stack 102. Each of the tiers 142 of the stack 140 may include at least one insulative structure 106 and at least one conductive structure 144 vertically adjacent the insulative structure 106. During the formation of the conductive structures 144, the configuration of the isolation structures 138 laterally interposed (e.g., laterally intervening) between the first slots 126 and the second slot 128 may substantially reduce (e.g., substantially prevent) so-called “overetch” near the intersections during processing. Laterally separating the first slots 126 from the second slot 128 using the isolation structures 138 of the isolation region 120 may eliminate the formation of corners between the converging slots. Further, the support structures 127 may be sized, shaped, positioned, and spaced to provide structural support to the stack 102 during the “replacement gate” processing acts performed on the electronic device 100.

The conductive structures 144 of the stack 140 may be formed of and include at least one conductive material. In some embodiments, the conductive structures 144 are formed of and include tungsten (W). In other embodiments, the conductive structures 144 are formed of and include conductively doped polysilicon. Each of the conductive structures 144 may individually include a substantially homogeneous distribution of the at least one conductive material, or a substantially heterogeneous distribution of the at least one conductive material. In some embodiments, each of the conductive structures 144 exhibits a substantially homogeneous distribution of conductive material. In additional embodiments, at least one of the conductive structures 144 exhibits a substantially heterogeneous distribution of at least one conductive material.

The conductive structures 144 of one or more vertically upper tiers 142 (e.g., a fourth tier 142d, a third tier 142c) of the stack 140 may be employed as select gate structures (e.g., drain side select gate (SGD) structures) for the blocks 132 of the stack 140. In addition, the conductive structures 144 of one or more vertically lower tiers 142 (e.g., a first tier 142a) of the stack 140 may be employed as additional select gate structures (e.g., source side select gate (SGS) structures) for the blocks 132 of the stack 140. The conductive structures 144 of one or more remaining tiers 142 (e.g., a second tier 142b) of the stack 140 may be employed as access line (e.g., word line) structures (e.g., access lines, access line plates, word lines, word line plates) for the blocks 132 of the stack 140.

The additional insulative structures 108 (FIG. 3B) of the tiers 110 (FIG. 3B) of the stack 102 (FIG. 3B) may be selectively removed by subjecting the stack 102 to at least one etching process (e.g., an isotropic etching process) employing an etch chemistry in which the additional insulative material of the additional insulative structures 108 is selectively removed relative to the insulative material of the insulative structures 106. By way of non-limiting example, if the insulative structures 106 are formed of and include SiO₂, and the additional insulative structures 108 are formed of and include Si₃N₄, the stack 102 may be exposed to an additional wet nitride strip (e.g., a second wet nitride strip) comprising a wet etchant comprising phosphoric acid (H₃PO₄) to selectively remove additional (e.g., remaining) portions of the additional insulative structures 108 adjacent to side surfaces of the blocks 132 exposed by one or more of the first slots 126 and the second slot 128. Thereafter, the conductive material may be formed (e.g., delivered, deposited) within void spaces resulting from the selective removal of the additional insulative material of the additional insulative structures 108 to form the conductive structures 144. As shown in FIG. 4B, the first slots 126 may individually be defined by the internal sidewalls 152, 154 (e.g., substantially linear sidewalls) of the materials (e.g., the insulative structures 106, the conductive structures 144) of the stack 140.

As shown in FIGS. 4C and 4D, end surfaces of the conductive structures 144 of the stack 140 adjacent to the second slot 128 are horizontally recessed relative to end surfaces of the insulative structures 106, and the isolation structures 138 are adjacent to the second slot 128 (e.g., interposed between the second slot 128 and the conductive structures 144). The second slot 128 may be defined by the internal sidewalls 156, 158 (e.g., substantially linear sidewalls) of the insulative structures 106 of the stack 140 and the isolation structures 138 within the isolation region 120. The isolation structures 138 are located external to the second slot 128 and horizontally overlapping ends of the first slots 126. Thus, at least some of the isolation structures 138 are laterally adjacent to (e.g., at an elevational level of) the conductive structures 144 of the stack 140 and vertically adjacent to the insulative structures 106 of the stack 140. The isolation structures 138 comprise one or more materials (e.g., dielectric material, barrier material) that are non-reactive with the conductive material of the conductive structures 144. As shown in FIG. 4D, segmented portions of the isolation structures 138 and the insulative structures 106 of the stack 140, may be present between the first slots 126 and the second slot 128 without being laterally adjacent to the conductive structures 144 of the stack 140.

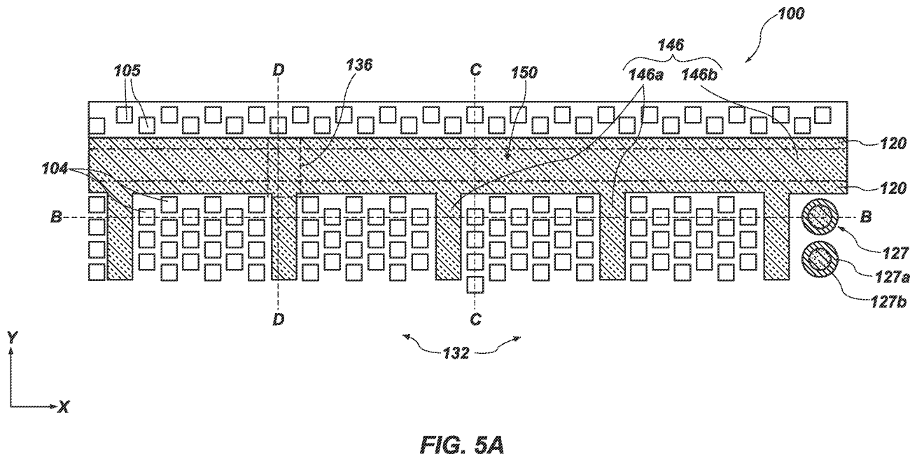

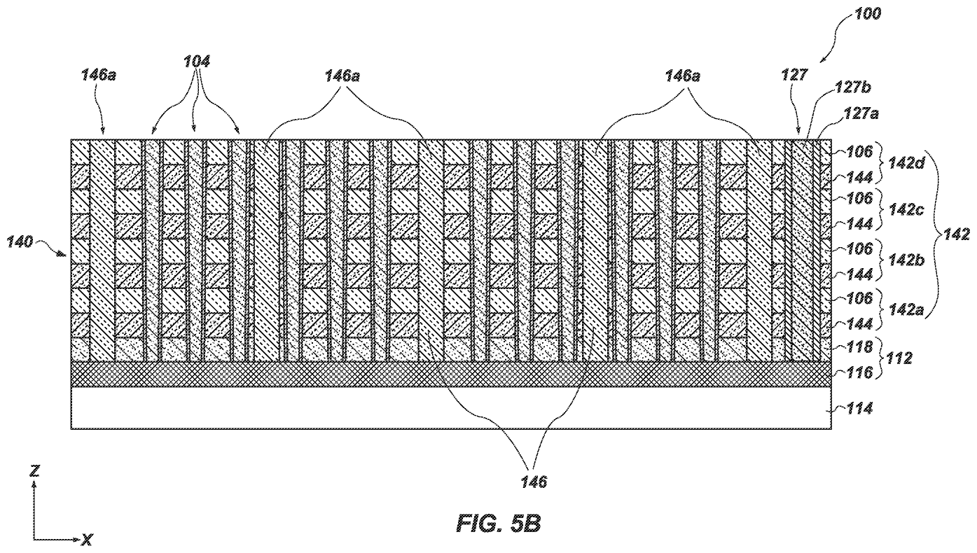

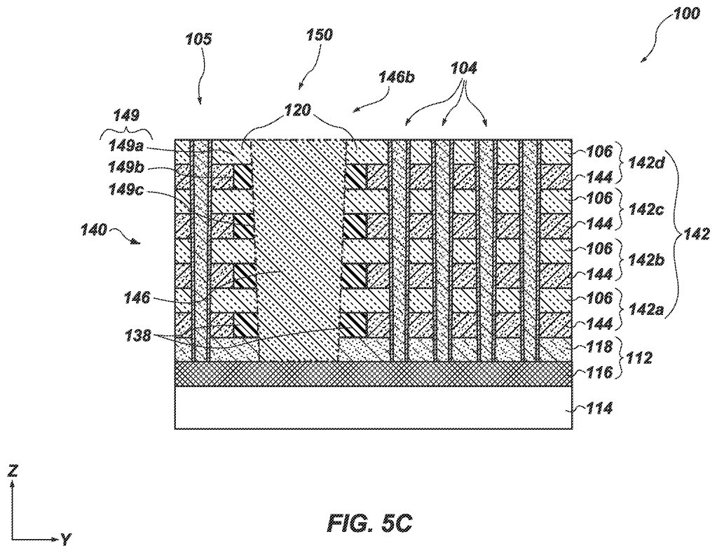

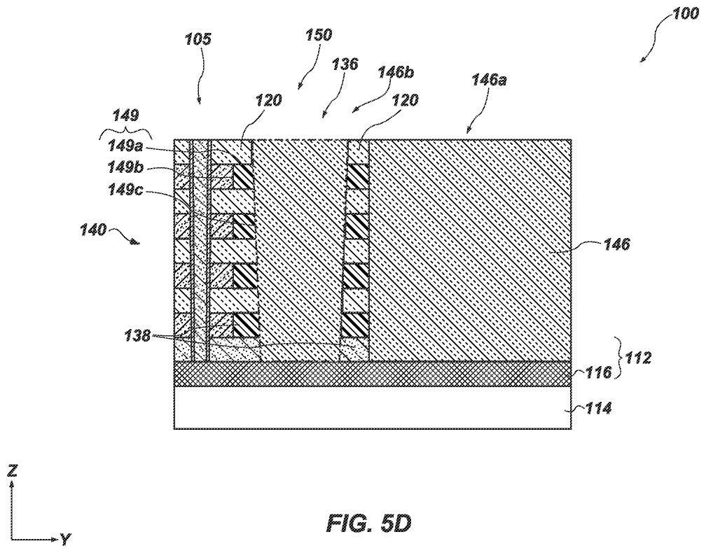

Referring to FIG. 5A, a dielectric material 146 may be formed within the first slots 126 (FIG. 4A) and the second slot 128 (FIG. 4A) following formation of the conductive structures 144 (FIG. 5B). The dielectric material 146 may at least partially (e.g., substantially) fill the first slots 126 and the second slot 128. FIGS. 5B, 5C, and 5D are simplified cross-sectional views of the electronic device 100 taken along the B-B line, the C-C line, and the D-D line, respectively, of FIG. 5A.

The dielectric material 146 may be formed of and include at least one insulative material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and MgOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). A material composition of the dielectric material 146 may be substantially the same as a material composition of one or more of the isolation structures 138 and the insulative structures 106 of the stack 140, or the material composition of the dielectric material 146 may be different than the material compositions of the isolation structures 138 and the insulative structures 106. In some embodiments, a material composition of the dielectric material 146 is substantially the same as a material composition of the isolation structures 138 (SiO₂).

As shown in FIG. 5A, the dielectric material 146 may include first portions 146a at least partially (e.g., substantially completely) filling the first slots 126 (FIG. 4A) and second portions 146b at least partially (e.g., substantially completely) filling the second slot 128 (FIG. 4A). The first portions 146a of the dielectric material 146 may extend in the second horizontal direction (e.g., the Y-direction), and the second portions 146b of the dielectric material 146 may extend in the first horizontal direction (e.g., the X-direction) transverse to the second horizontal direction. Since the isolation structures 138 (FIGS. 5C and 5D) are laterally interposed between the second slot 128 and the first slots 126, the isolation structures 138 are laterally interposed between the first portions 146a of the dielectric material 146 and the second portions 146b thereof. In other words, the first portions 146a of the dielectric material 146 do not intersect the second portions 146b thereof. Rather, the first portions 146a of the dielectric material 146 are proximal the second portions 146b thereof within the intersection regions 136 and separated therefrom (e.g., isolated therefrom) by the isolation structures 138.

The first portions 146a of the dielectric material 146 may horizontally intervene (e.g., in the X-direction) between the horizontally neighboring blocks 132 of the first pillars 104. In some embodiments, a minimum distance between the first pillars 104 and the dielectric material 146 is within a range of from about 50 nm to about 200 nm, such as from about 50 nm to about 100 nm, from about 100 nm to about 150 nm, or from about 150 nm to about 200 nm. The second portions 146b of the dielectric material 146 may continuously extend (e.g., in the X-direction), without being integral with the first portions 146a of the dielectric material 146.

As shown in FIG. 5B, each of the first portions 146a of the dielectric material 146 may extend vertically completely through the stack 140. For example, each of the first portions 146a of the dielectric material 146 may extend vertically (e.g., in the Z-direction) from a vertically uppermost boundary of a vertically uppermost tier 142 (e.g., the fourth tier 142d) of the stack 140 to the upper surface of the source structure 116 underlying the stack 140. Since portions of the first slots 126 (FIG. 4B) may be defined by substantially linear sidewalls in the Z-direction of the stack 102 (FIG. 4B), the first portions 146a of the dielectric material 146 may include substantially linear sidewalls in contact (e.g., direct contact) and coincident with the substantially linear sidewalls of the stack 140 (e.g., including the substantially linear sidewalls of the insulative structures 106).

As shown in FIGS. 5C and 5D, the second portions 146b of the dielectric material 146 may extend vertically completely through the stack 140. For example, the second portions 146b of the dielectric material 146 may extend vertically (e.g., in the Z-direction) from a vertically uppermost boundary of a vertically uppermost tier 142 (e.g., the fourth tier 142d) of the stack 140 to the upper surface of the source structure 116 underlying the stack 140. Since the second slot 128 (FIG. 4B) may be defined by substantially linear sidewalls in the Z-direction of the stack 102 (FIG. 4B), the second portions 146b of the dielectric material 146 may include substantially linear sidewalls in contact (e.g., direct contact) and coincident with the substantially linear sidewalls of the stack 140 (e.g., including the substantially linear sidewalls of the insulative structures 106). In addition, since the isolation structures 138 are laterally adjacent to the conductive structures 144, the dielectric material 146 is in contact (e.g., direct contact) and coincident with the isolation structures 138, without being in contact with the conductive structures 144 of the stack 140. Further, the isolation structures 138 may be laterally adjacent to the first pillars 104 in at least one horizontal direction (e.g., the Y-direction) and separated therefrom by portions of the conductive structures 144 of the stack 140.

The dielectric material 146 may be formed using conventional processes (e.g., conventional deposition processes) and conventional processing equipment. For example, the first portions 146a of the dielectric material 146 may be formed within the first slots 126 (FIG. 4A) and the second portions 146b thereof may be formed within the second slot 128 (FIG. 4A) using one or more conventional material deposition processes (e.g., a conventional CVD process, a conventional ALD process).

The electronic device 100 may include a dielectric structure 150 (FIG. 5A) including the dielectric material 146 (e.g., second portions 146b thereof) within and at least partially filling the second slot 128 (FIG. 4A). For example, the dielectric structure 150 may extend vertically through the stack 140 to the upper surface of the source structure 116 and horizontally extend in the X-direction. The dielectric structure 150 (e.g., a dielectric-filled slot, a slot structure) is defined between the internal sidewalls 156, 158 (FIG. 4C) of the stack 140. Further, the dielectric structure 150 is separated from the conductive structures 144 of the stack 140 by the isolation structures 138 (FIGS. 5C and 5D), without being in contact with the conductive structures 144. Accordingly, the dielectric structure 150 is in contact (e.g., direct contact) and coincident with the isolation structures 138, without being in contact with the conductive structures 144 of the stack 140. The dielectric structure 150 may be substantially uniform (e.g., constant, non-variable) across a height of the stack 140 or, alternatively, the dielectric structure 150 may exhibit a tapered profile with an upper portion thereof having a greater critical dimension (e.g., width) than a lower portion thereof. For example, an outer boundary of the isolation region 120 including the isolation structures 138 may be relatively wider than an outer boundary of the dielectric structure 150 in the second horizontal direction (e.g., the Y-direction).

As shown in FIGS. 5C and 5D, the isolation structures 138 may contact surrounding materials along interfaces 149. For example, one or more surfaces (e.g., upper surfaces, lower surfaces) of at least some of the isolation structures 138 may directly contact surfaces (e.g., lower surfaces, upper surfaces) of the insulative structures 106 along interfaces 149a (e.g., horizontal interfaces). Further, one or more side surfaces (e.g., lateral side surfaces, horizontal side surfaces) of the individual isolation structures 138 may directly contact side surfaces of the conductive structures 144 of the stack 140 along an interface 149b (e.g., a vertical interface). In some embodiments, segmented portions of the isolation structures 138 vertically intervene between the insulative structures 106 of the tiers 142 and separate the first portions 146a of the dielectric material 146 from the second portions 146b thereof, as shown in FIG. 5D. In other embodiments, the isolation region 120 on the right-hand side of FIG. 5D may include the first portions 146a of the dielectric material 146 directly adjacent to the dielectric structure 150, such as when the first slots 126 initial intersect the second slot 128.

As shown in FIGS. 5C and 5D, one or more additional side surfaces (e.g., lateral side surfaces, horizontal side surfaces) of the isolation structures 138 may directly contact side surfaces of the dielectric structure 150 including the dielectric material 146 along an interface 149c (e.g., a vertical interface). For example, inner lateral surfaces of the isolation structures 138 may abut against an outer lateral surface of the dielectric structure 150 along the interface 149c, which interface 149c defines a boundary between the individual isolation structures 138 and the dielectric structure 150. Accordingly, the side surfaces (e.g., sidewalls) of the isolation structures 138 abut portions of the conductive structures 144 of the stack 140 at a location external to the interface 149c between the dielectric structure 150 and the isolation structures 138. The interfaces 149b, 149c may extend in a direction substantially parallel to a longitudinal axis of the first pillars 104 and substantially transverse to a major surface of the source tier 112. Following the formation of the dielectric material 146, the electronic device 100 may be subjected to additional processing.

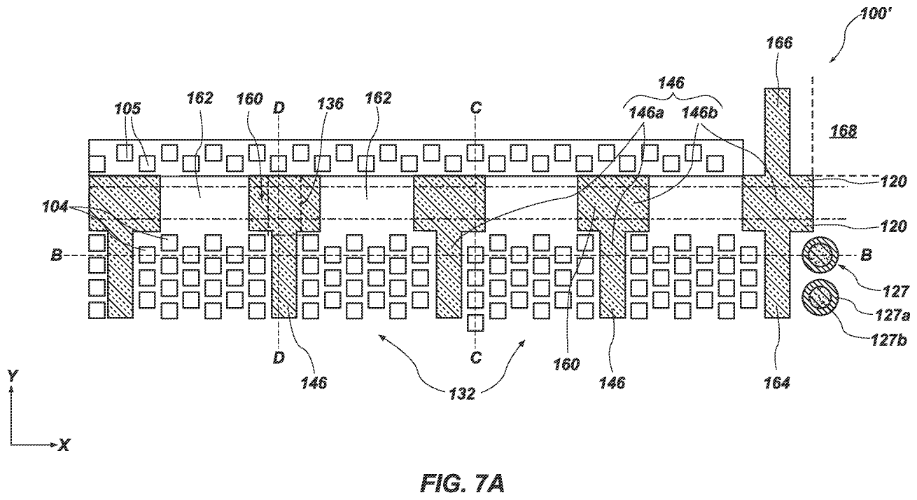

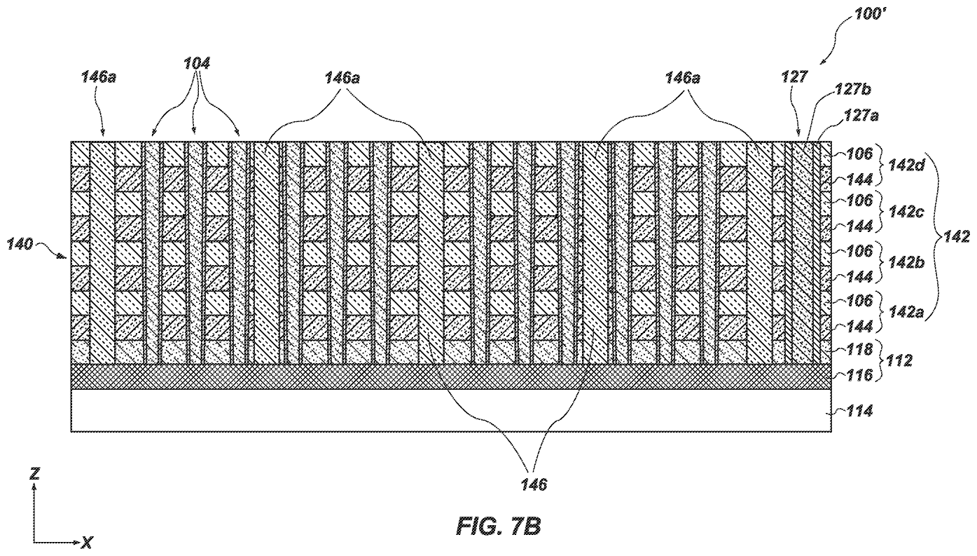

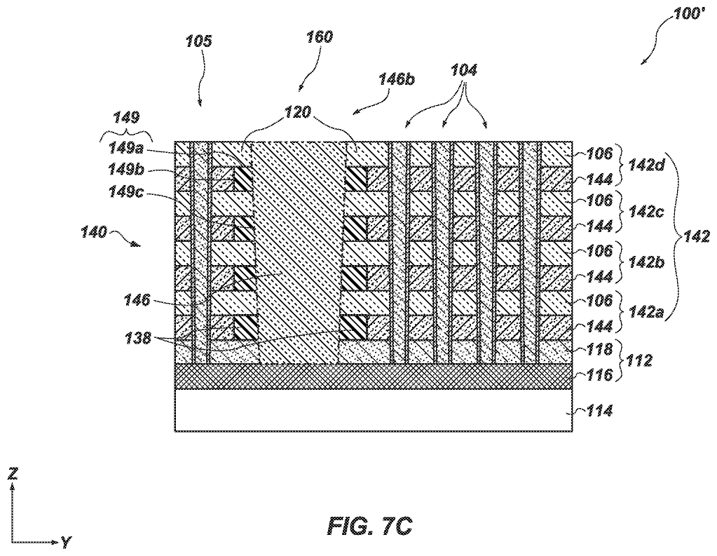

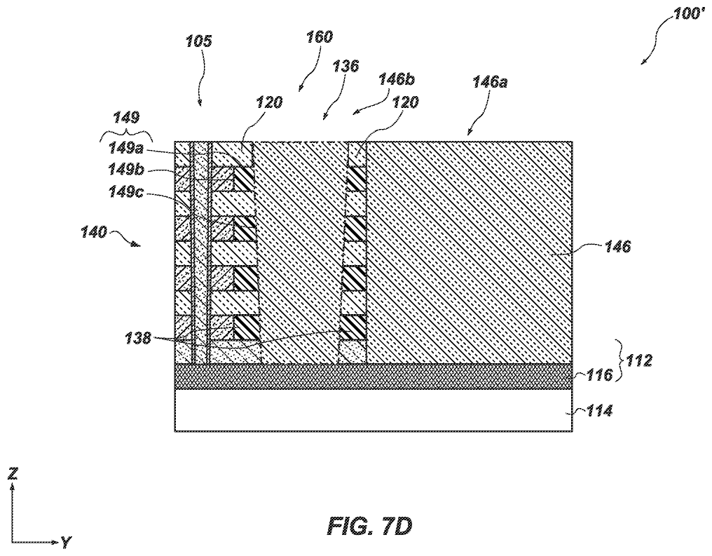

One of ordinary skill in the art will appreciate that, in accordance with additional embodiments of the disclosure, the features and feature configurations described above in relation to FIGS. 1A through 5D may be adapted to design needs of different electronic devices (e.g., different memory devices) depending on desired electrical performance properties of the electronic devices. By way of non-limiting example, in accordance with additional embodiments of the disclosure, FIGS. 6A through 7D are simplified, partial top-down views (i.e., FIGS. 6A and 7A) and simplified, partial cross-sectional views (i.e., FIGS. 6B through 6D and 7B through 7D) of a method of forming an electronic device having a different configuration than the electronic device 100. Throughout the remaining description and the accompanying figures, functionally similar features (e.g., structures, devices) are referred to with similar reference numerals. To avoid repetition, not all features shown in the remaining figures (including FIGS. 6A through 7D) are described in detail herein. Rather, unless described otherwise below, a feature designated by a reference numeral of a previously described feature (whether the previously described feature is first described before the present paragraph, or is first described after the present paragraph) will be understood to be substantially similar to the previously described feature.

FIG. 6A is a simplified, partial top-down view of an electronic device 100′ (e.g., a memory device, such as a 3D NAND Flash memory device). At the processing stage depicted in FIG. 6A, the electronic device 100′ may be substantially similar to the electronic device 100 at the processing stage depicted in FIG. 2A. FIGS. 6B, 6C, and 6D are simplified cross-sectional views of the electronic device 100′ taken along the B-B line, the C-C line, and the D-D line, respectively, of FIG. 6A. For clarity and ease of understanding of the drawings and related description, not all features depicted in one of FIGS. 6A through 6D are depicted in each of the others of FIGS. 6A through 6D, which applies equally to FIGS. 7A through 7D.

The electronic device 100′ illustrated in FIGS. 6A through 6D includes the stack 102, and the first pillars 104 and the second pillars 105 extending vertically through the stack 102. The stack 102 of the electronic device 100′ may also be formed to include the vertically alternating (e.g., in the Z-direction) sequence of the insulative structures 106 and the additional insulative structures 108 arranged in the tiers 110 (e.g., the tiers 110a-110d). The electronic device 100′ may be formed to include the source tier 112 vertically under the stack 102 and the at least one base structure 114 vertically under the source tier 112. The source tier 112 may include the at least one source structure 116 and, optionally, the at least one insulative material 118 vertically adjacent the source structure 116.

Referring to FIG. 6A, the first slots 126 may be formed to extend vertically into the stack 102 (FIG. 6B). In addition, block openings 148 (e.g., segmented openings) may be formed to extend vertically into the stack 102 in regions corresponding to locations of the second slot 128 (FIG. 2A). The first slots 126 may be formed within the first slot regions 122 (FIG. 1A) and the block openings 148 may be formed within the at least one second slot region 124 (FIG. 1A). At least some (e.g., each) of the first slots 126 of the additional embodiments of the disclosure described herein with reference to FIGS. 6A through 7D may be disposed at a horizontal end in the Y-direction of the block openings 148. In addition, the openings 117 of the support structures 127 (see FIG. 7A) may be formed to extend vertically into the portions of the stack 102 between at least some of the first slots 126.

The electronic device 100′ may be formed to include the isolation region 120 including one or more (e.g., two opposing) portions extending in the first horizontal direction and adjacent to the segmented portions of the block openings 148. The isolation region 120 may facilitate a desired horizontal distance between the block openings 148 and each of the first pillars 104 and the second pillars 105, and to facilitate desired horizontal spacing (e.g., in the Y-direction) between the first slots 126 and the block openings 148. In other words, the isolation region 120 separates the first slots 126 from the block openings 148. The isolation region 120 may include the two opposing portions or, alternatively, the isolation region 120 may include only one (e.g., a single) portion between the block openings 148 and the first pillars 104 (e.g., between the block openings 148 and the first slots 126), without an additional portion of the isolation region 120 being formed between the block openings 148 and the second pillars 105.

In some embodiments, the first slots 126 may initially be formed to intersect the block openings 148 at the intersections 130 within the intersection regions 136. In other embodiments, end portions of at least some (e.g., each) of the first slots 126 are formed proximal to the block openings 148 within the intersection regions 136, without intersecting (e.g., meeting) the block openings 148 at the intersections 130. For example, remaining portions of the tiers 110 (FIG. 6B) of the stack 102 (FIG. 6B) may laterally intervene between the first slots 126 and the block openings 148 within the opposing portions of the isolation region 120, as shown in a first one of the first slots 126 on the left-hand side of FIG. 6A. In other words, the first slots 126 and the block openings 148 may initially be formed to be proximal one another within the intersection regions 136, and remaining portions of the materials (e.g., the insulative structures 106, the additional insulative structures 108) of the stack 102 may separate the first slots 126 from the block openings 148. Accordingly, portions of the materials of the stack 102 may remain in the isolation region 120 between at least some (e.g. each) of the first slots 126 and the block openings 148, as shown for clarity and convenience throughout the remaining description and the accompanying figures. The block openings 148 of the electronic device 100′, as shown in FIG. 6A, may include discrete (e.g., discontinuous) structures in the first horizontal direction that may be segmented by isolation regions 162, which configuration differs from a substantially continuous structure of the second slot 128 of the electronic device 100, as shown in FIG. 2A.

In the additional embodiments of the electronic device 100′, a continuous slot (e.g., the second slot 128 (FIG. 2A)) may not be formed to extend between each of the segmented portions of the block openings 148. Rather, the isolation regions 162 (e.g., regions devoid of slots, regions devoid of pillars) may extend between at least some of the segmented portions of the block openings 148, as shown in FIG. 6A. Accordingly, remaining portions of the materials (e.g., the insulative structures 106, the additional insulative structures 108) of the stack 102 (FIG. 6B) may extend between the block openings 148 within the isolation regions 162, without forming portions of a continuous slot therein and without forming pillars or support structures therein. In other words, openings (e.g., slots) may not be formed within the isolation regions 162, such that the materials of the stack 102 remain intact between the segmented portions of the block openings 148 to provide additional structural support to the tiers 110 (FIG. 6B) of the stack 102.

In other embodiments, additional pillars or structures (e.g., the first pillars 104, the second pillars 105, the openings 117 of the support structures 127 (see FIG. 7A)) may extend within the isolation regions 162 between at least some of the block openings 148. In other words, slots may not be formed within the isolation regions 162, such that one or more of pillars and support structures extend vertically through the materials of the stack 102 (FIG. 6B) between the segmented portions of the block openings 148 to provide additional structural support to the tiers 110 (FIG. 6B) of the stack 102. Accordingly, the block openings 148 may be discontinuous and discrete from one another in the X-direction. As used herein, the term “discrete” means and includes a material or structure that is defined by one or more differing materials or structures. For example, the materials (e.g., the insulative structures 106, the additional insulative structures 108) of the stack 102 laterally intervene (e.g., in the first horizontal direction) within the isolation regions 162 between the block openings 148. Accordingly, the block openings 148 may be considered to be formed of and include multiple, relatively smaller portions of continuous slots separated from one another by intervening portions of the materials of the stack 102.

The first slots 126 may or may not be formed substantially simultaneously with formation of the block openings 148. In some embodiments, the first slots 126 and the block openings 148 may be formed using a single material removal act. However, additional material removal processes may be contemplated. For example, the first slots 126 may be formed before or after formation of the block openings 148. In additional embodiments, one or more of the first slots 126 and the block openings 148 may be formed during additional material removal processes used to form additional features (e.g., openings, structures) that extend vertically substantially completely through the stack 102. Such features may include, for example, pillars, staircase structures, etc.

The openings 117 may be formed within the support structure regions 107 (FIG. 1A) and may be proximate to one or more of the first slots 126 and the block openings 148. The openings 117 extend vertically through the stack 102 and exhibit a height substantially similar to (e.g., the same as) a height of the first slots 126. The openings 117 may be formed during the same material removal act used to form one or more of the first slots 126 and the block openings 148 or, alternatively, using one or more additional material removal acts. For example, the openings 117 may be formed during formation of the block openings 148 using a single (e.g., one) masking act to reduce cost and the number of process acts conducted. In additional embodiments, the support structures 127 (see FIG. 7A) may be formed in the openings 117 prior to forming one or more of the first slots 126 and the block openings 148.

The first slots 126 and the block openings 148 may each be formed to extend vertically substantially completely through the stack 102 (FIG. 6B). Neighboring blocks 132 each including one or more of the first pillars 104 and the openings 117 may be horizontally separated from one another by the first slots 126. As shown in FIG. 6B, the first slots 126 may be located external to the intersections 130 (FIG. 6A) and may individually be defined by the internal sidewalls 152, 154 (e.g., substantially linear sidewalls) of the materials (e.g., the insulative structures 106, the additional insulative structures 108) of the stack 102.

As shown in FIGS. 6C and 6D, the block openings 148 may be located external to the intersections 130 (FIG. 6A) and may individually be defined by the internal sidewalls 156, 158 (e.g., substantially linear sidewalls) of the materials (e.g., the insulative structures 106, the additional insulative structures 108) of the stack 102. The block openings 148 may exhibit a tapered profile in at least one horizontal direction (e.g., the Y-direction) with an upper portion of the block openings 148 having a greater critical dimension (e.g., width) than a lower portion thereof. However, as shown in FIG. 6A, configurations of the second slot region 124 (FIG. 1A) may be modified relative to the configurations thereof previously described with reference to FIGS. 1A through 5D to spatially accommodate the block openings 148 segmented by the isolation regions 162.

Individual block openings 148 of the electronic device 100′, as shown in FIG. 6A, may exhibit a fourth width W₄ in the X-direction that is relatively greater than the first width W₁ of the first slots 126 in the X-direction. The fourth width W₄ of the block openings 148 may, for example, be within a range of from about 200 percent to about 500 percent (e.g., from about 200 percent to about 300 percent, from about 300 percent to about 400 percent, from about 400 percent to about 500 percent) larger than the first width W₁. The fourth width W₄ may be between about 2 and 10 times (e.g., an order of magnitude) greater than the first width W₁. By way of non-limiting example, the first width W₁ may be within a range from about 200 nm to about 300 nm and the fourth width W₄ may be within a range from about 400 nm (e.g., 0.4 μm) to about 2000 nm (e.g., 2 μm), although other configurations may be contemplated. For example, the fourth width W₄ may be within a range from about 2 μm to about 4 μm, from about 4 μm to about 6 μm, from about 6 μm to about 8 μm, or even larger, depending on design requirements of the electronic device 100′.

The block openings 148 may exhibit a different configuration (e.g., size and shape) than the first slots 126. For example, the first slots 126 may exhibit a rectangular prism shape having a substantially rectangular horizontal cross-sectional shape extending in the Y-direction. The block openings 148 may also exhibit a rectangular prism shape having a substantially rectangular horizontal cross-sectional shape extending in the X-direction. In other words, the block openings 148 may have a relatively greater dimension (e.g., a width) in the X-direction than in the Y-direction. Alternatively, the block openings 148 may have a relatively greater dimension in the Y-direction than in the X-direction. In additional embodiments, the block openings 148 may have a substantially square cross-sectional shape having dimensions in the X-direction and the Y-direction that are substantially the same.

The configuration of the block openings 148 may provide increased structural support proximate a perimeter of (or, alternatively, within) the array region, and/or at the intersections 130 within the intersection regions 136 of the first slots 126 and the block openings 148, without undesirably increasing the overall width (e.g., horizontal footprint) of the array region. For example, the block openings 148 segmented by the isolation regions 162 may provide enhanced structural integrity than may otherwise be facilitated by slots that extend continuously at substantially the same horizontal position as the second slot 128 (FIG. 2A) of the previous embodiment. The block openings 148 may be formed within a horizontal area of the array region, as well as within non-array regions of the electronic device 100′.

The methods of the disclosure may reduce or eliminate process acts, such as the formation of complex configurations of the intersections 130, conventionally employed to form conventional electronic devices having functions similar to the electronic device 100′. The configuration of the block openings 148 may also facilitate a substantially even (e.g., uniform) distribution of stresses with a subsequently formed stack. For example, the block openings 148 may reduce distortion (e.g., bowing, bending, warping, etc.) within the subsequently formed stack so as to substantially inhibit (e.g., impede, prevent) the occurrence of so-called “bowing” of the subsequently formed stack.

Following formation of the block openings 148, lateral portions of the additional insulative structures 108 may be selectively removed through the block openings 148 to form the separation regions 134, as shown in FIGS. 6C and 6D. Accordingly, end surfaces of the additional insulative structures 108 of the stack 102 adjacent to the block openings 148 are horizontally recessed relative to end surfaces of the insulative structures 106. The separation regions 134 are formed within the opposing portions of the isolation region 120 and external to (e.g., outside of) a horizontal area of the block openings 148 defined by the internal sidewalls 156, 158. The separation regions 134 horizontally overlap ends of the first slots 126, such that the separation regions 134 extend some distance beyond ends of the first slots 126, as shown in FIG. 6A. While FIGS. 6A through 6D illustrate the first slots 126 (FIG. 6B) being formed prior to formation of the separation regions 134 for clarity, the disclosure is not so limited, and the first slots 126 may be formed following formation of the separation regions 134.

Referring to FIG. 7A, the isolation structures 138 may be formed within the separation regions 134 (FIGS. 6C and 6D) of the isolation region 120 on one or more (e.g., two opposing) sides of the block openings 148 (FIG. 6A), and the support structures 127 may be formed within the openings 117 (FIG. 6A). The electronic device 100′ may then be subjected to a “replacement gate” or “gate last” process to convert the stack 102 (FIG. 6B) into the stack 140 (FIG. 7B). In addition, the dielectric material 146 may be formed within the first slots 126 (FIG. 6A) and the block openings 148 following formation of the conductive structures 144 (FIG. 7B). FIGS. 7B, 7C, and 7D are simplified cross-sectional views of the electronic device 100′ taken along the B-B line, the C-C line, and the D-D line, respectively, of FIG. 7A.

The electronic device 100′ illustrated in FIGS. 7A through 7D includes the isolation structures 138 including one or more dielectric materials (e.g., barrier material) formed within the separation regions 134 (FIGS. 6C and 6D). For example, the isolation structures 138 may be formed to extend between vertically neighboring insulative structures 106 proximate the block openings 148 (FIG. 6A), such that the isolation structures 138 substantially vertically fill the separation regions 134. Accordingly, the isolation structures 138 may be formed to extend from upper surfaces of the insulative structures 106 to lower surfaces of vertically neighboring insulative structures 106.

Accordingly, the isolation structures 138 are located external to horizontal areas of the block openings 148 (FIG. 6A) and horizontally overlap ends of the first slots 126 (FIG. 6A), such that the isolation structures 138 extend beyond the ends of the first slots 126. Whether the first slots 126 are initially formed to intersect the block openings 148 or initially formed separate therefrom, the isolation structures 138 are laterally interposed between the 148 and the first slots 126 at the process stage of FIGS. 7A through 7D. In some embodiments, segmented portions of the isolation structures 138 may be laterally adjacent to the additional insulative structures 108 (FIG. 6B) of the stack 102 (FIG. 6B) and vertically adjacent to the insulative structures 106 of the stack 102, such that the isolation structures 138 vertically intervene between vertically neighboring insulative structures 106. In other embodiments, at least one of the opposing portions of the isolation region 120 comprises one or more materials (e.g., dielectric material, barrier material) between the first slots 126 and the block openings 148.

As shown in FIGS. 7C and 7D, the isolation structures 138 may contact surrounding materials along interfaces 149. For example, one or more surfaces (e.g., upper surfaces, lower surfaces) of at least some of the isolation structures 138 may directly contact surfaces (e.g., lower surfaces, upper surfaces) of the insulative structures 106 along the interfaces 149a (e.g., horizontal interfaces). Further, one or more side surfaces (e.g., lateral side surfaces, horizontal side surfaces) of the individual isolation structures 138 may directly contact side surfaces of the conductive structures 144 of the stack 140 along the interface 149b (e.g., a vertical interface). Segmented portions of the isolation structures 138 vertically intervene between the insulative structures 106 of the tiers 142 and separate the first portions 146a of the dielectric material 146 from the second portions 146b thereof, as shown in FIG. 7D. In other embodiments, the isolation region 120 on the right-hand side of FIG. 7D may include the first portions 146a of the dielectric material 146 directly adjacent to the block structures 160, such as when the first slots 126 initial intersect the block openings 148.

As shown in FIG. 7B, following formation of the isolation structures 138, the stack 140 may be formed to include the vertically alternating (e.g., in the Z-direction) sequence of the insulative structures 106 and the conductive structures 144 arranged in the tiers 142 (e.g., the tiers 142a-142d). During the formation of the conductive structures 144, the configuration of the block openings 148 (FIG. 6A) may inhibit (e.g., prevent) the undesirable tier deformations (e.g., tier warping) and/or tier collapse during the formation of the tiers 142, such as to mitigate the risk of undesirable current leakage and short circuits by providing increased structural support during use and operation of the electronic device 100′.

As shown in FIG. 7A in combination with FIG. 7B, the support structures 127 may be formed in the openings 117 (FIG. 6A) extending vertically through the tiers 142 of the stack 140, as shown in FIGS. 7A and 7B. For example, the support structures 127 may be formed in the openings 117 extending vertically through the tiers 110 (FIG. 6B) of the stack 102 (FIG. 6B) prior to subjecting the electronic device 100′ to the replacement gate process. The support structures 127 may individually include the liner 127a, and the fill material 127b surrounded by the liner 127a. In some embodiments, the liner 127a may be formed during formation of the isolation structures 138, as described in greater detail with reference to FIG. 3A. In other embodiments, the support structures 127 may be formed prior to forming the isolation structures 138.

As shown in FIG. 7A, the dielectric material 146 may be formed within the first slots 126 (FIG. 6A) and the block openings 148 (FIG. 6A). The dielectric material 146 may at least partially (e.g., substantially completely) fill the first slots 126 and the block openings 148. The dielectric material 146 may include the first portions 146a of the dielectric material 146 within the first slots 126 and second portions 146b thereof within the block openings 148. Since, the isolation structures 138 are laterally interposed between the block openings 148 and the first slots 126, the isolation structures 138 are laterally interposed between the first portions 146a of the dielectric material 146 and the second portions 146b thereof. In other words, the first portions 146a of the dielectric material 146 do not intersect the second portions 146b thereof. Rather, the first portions 146a of the dielectric material 146 are proximal the second portions 146b thereof within the intersection regions 136 and separated therefrom (e.g., isolated therefrom) by the isolation structures 138.

As shown in FIG. 7B, each of the first portions 146a of the dielectric material 146 may extend vertically completely through the stack 140, as described in greater detail with reference to FIG. 5B. Since the first slots 126 (FIG. 6B) may be defined by substantially linear sidewalls in the Z-direction of the stack 102 (FIG. 6B), the first portions 146a of the dielectric material 146 may include substantially linear sidewalls in contact (e.g., direct contact) and coincident with the substantially linear sidewalls of the stack 140 (e.g., including the substantially linear sidewalls of the insulative structures 106 and the conductive structures 144 thereof). In addition, since the block openings 148 (FIGS. 6C and 6D) may include the substantially linear sidewalls, the second portions 146b of the dielectric material 146 may also include substantially linear sidewalls in contact (e.g., direct contact) and coincident with the substantially linear sidewalls of the stack 140 (e.g., including the substantially linear sidewalls of the insulative structures 106) and the isolation structures 138.

The electronic device 100′ may include block structures 160 (FIG. 7A) including the dielectric material 146 (e.g., one or more dielectric materials) within and at least partially filling the block openings 148 (FIG. 6A). For example, the block structures 160 (e.g., dielectric block structures, slot structures, dielectric-filled slots) may extend vertically through the stack 140 to the upper surface of the source structure 116 and horizontally extend in the X-direction. The block structures 160 may extend vertically to or beyond a vertically lowermost boundary of a vertically lowermost tier 142 (e.g., the first tier 142a) of the stack 140. The block structures 160 of the electronic device 100′ may include discrete (e.g., discontinuous) structures in the first horizontal direction that may be segmented by the isolation regions 162. An outer boundary of the isolation region 120 including the isolation structures 138 is relatively wider than outer boundaries of the block structures 160 in the second horizontal direction (e.g., the Y-direction). The block structures 160 are defined between the internal sidewalls 156, 158 (FIG. 6C) of the stack 140 and spaced apart from one another in the first horizontal direction (e.g., the X-direction). As shown in FIG. 7A, segmented portions of the block structures 160 including the dielectric material 146 may be discontinuous and discrete from one another. Further, the block structures 160 are separated from the conductive structures 144 of the stack 140 by the isolation structures 138, without being in contact with the conductive structures 144. Following the formation of the dielectric material 146, the electronic device 100′ may be subjected to additional processing.

As shown in FIG. 7C, one or more additional side surfaces (e.g., lateral side surfaces, horizontal side surfaces) of the isolation structures 138 may directly contact side surfaces of the block structures 160 including the dielectric material 146 along the interface 149c (e.g., a vertical interface). For example, inner lateral surfaces of the isolation structures 138 may abut against outer lateral surfaces of the block structures 160 along the interface 149c, which interface 149c defines a boundary between the individual isolation structures 138 and the block structures 160. Accordingly, the side surfaces (e.g., sidewalls) of the isolation structures 138 abut portions of the conductive structures 144 of the stack 140 at a location external to the interface 149c between the block structures 160 and the isolation structures 138.

While FIG. 7A illustrates a single (e.g., only one) row of the block structures 160 proximate a perimeter (e.g., outer horizontal boundaries) of the stack 140 (FIG. 7B), additional configurations may be contemplated. For example, the block structures 160 may be centrally located within the stack 140 in the second horizontal direction (e.g., the Y-direction) and relatively remote from the perimeter of the stack 140. In additional embodiments, multiple (e.g., two or more) rows of the block structures 160 may be formed horizontally proximate one another in the second horizontal direction.

As shown in FIG. 7A, additional first slots 126 (FIG. 6A) (e.g., additional dielectric-filled slots, additional slot structures) including the first portions 146a of the dielectric material 146 may be formed on opposing sides (e.g., in the Y-direction) of the block structures 160 within the intersection regions 136. For example, two of the additional dielectric-filled slots may be adjacent to one of the block structures 160 in the second horizontal direction, as shown on the right-hand side of FIG. 7A. The additional dielectric-filled slots may be formed in a first plane 164 and in a second plane 166 and separated from the block structures 160 by the isolation structures 138 (FIGS. 7C and 7D) within the isolation region 120. The additional dielectric-filled slots of the first plane 164 may be formed at substantially the same time as the additional dielectric-filled slots of the second plane 166. For example, the first slots 126 of the first plane 164 may be formed during formation of the first slots 126 of the second plane 166, and the first portions 146a of the dielectric material 146 may be formed therein at substantially the same time. While FIG. 7A illustrates additional block structures 160 associated with only one additional slot for clarity, the disclosure is not so limited, and additional (e.g., each) of the block structures 160 may be associated with two of the additional dielectric-filled slots. Further, the additional dielectric-filled slots of the first slots 126 may be formed in the first plane 164 and in the second plane 166 on opposing sides of the dielectric structure 150 (FIG. 5A) in the previous embodiments of the electronic device 100 of FIGS. 1A through 5D.

While the end portions of the additional insulative structures 108 (FIG. 6B) of the stack 102 (FIG. 6B) have been removed (e.g., are not present) in the perspective of FIGS. 6C and 6D prior to formation of the conductive structures 144 (FIG. 7B) of the stack 140 (FIG. 7B), the additional insulative structures 108, including the end portions thereof, may be present in other portions (e.g., peripheral regions 168) of the electronic device 100′, such as in portions of the electronic device 100′ distal to the block structures 160 and the isolation region 120 including the isolation structures 138 (FIGS. 7C and 7D). The additional insulative structures 108 and/or the conductive structures 144 may be present (e.g., visible) in their entirety, for example, in the peripheral regions 168 of the electronic device 100′. In other words, the additional insulative structures 108 and/or the conductive structures 144 may be positioned between neighboring portions of the insulative structures 106 of the stack 140 in the peripheral regions 168 of the electronic device 100′ with end surfaces being substantially aligned (e.g., substantially coplanar) with end surfaces of the insulative structures 106. Therefore, although the isolation structures 138 are present between the neighboring portions of the insulative structures 106 of the electronic device 100′ in the perspective shown in FIGS. 7C and 7D, the peripheral regions 168 of the electronic device 100′ will include the additional insulative structures 108 and/or the conductive structures 144 in their entirety between the neighboring portions of the insulative structures 106 without including the isolation structures 138, which applies equally to the previous embodiments of the electronic device 100 of FIGS. 1A through 5D.

As described above, forming the electronic device 100 of the embodiment of FIGS. 1A through 5D to include the isolation structures 138 of the isolation region 120 laterally interposed (e.g., intervening) between the first slots 126 and the second slot 128 including the dielectric structure 150 may facilitate improved performance of the electronic device 100. Similarly, forming the electronic device 100′ of the embodiment of FIGS. 6A through 7D to include the isolation structures 138 of the isolation region 120 laterally interposed between the first slots 126 and the block openings 148 including the block structures 160 may facilitate improved performance of the electronic device 100′. Whether the dielectric structure 150 (e.g., dielectric-filled slots) of the electronic device 100 includes a continuous slot or the block structures 160 (e.g., dielectric block structures) of the electronic device 100′ include discrete (e.g., discontinuous) structures segmented by the isolation regions 162, the isolation structures 138 are laterally interposed between the first slots 126 including the dielectric material 146 (e.g., additional dielectric-filled slots) and one or more of the dielectric structure 150 and the block structures 160.

One or more electronic devices 100, 100′ according to embodiments of the disclosure may be present in an apparatus or in an electronic system. The electronic devices 100, 100′, the apparatus including the one or more electronic devices 100, 100′, or the electronic system including the one or more electronic devices 100, 100′ may include additional components, which are formed by conventional techniques. The additional components may include, but are not limited to, staircase structures, interdeck structures, contacts, interconnects, data lines (e.g., bit lines), etc. The additional components may be formed during the fabrication of the electronic devices 100, 100′ or after the electronic devices 100, 100′ have been fabricated. By way of example only, one or more of the additional components may be formed before or after the isolation structures 138 of the isolation region 120 are formed, while other additional components may be formed after the electronic devices 100, 100′ have been fabricated. The additional components may be present in locations of the electronic devices 100, 100′ or the apparatus that are not depicted in the perspectives of FIGS. 1A through 7D.

The structures and methods for laterally separating the slots from one another near the intersections using the isolation structures described herein may provide advantages over conventional electronic devices and methods for forming electronic devices. For example, conventional material removal processes typically utilized to form conventional slots within a stack may result in unintentional micro-slots being formed near the intersections of the slots and may cause failure of the electronic device. In contrast, forming the isolation structures 138 of the isolation region 120 to separate the slots (e.g., the first slots 126, the second slot 128, the block openings 148) from one another may reduce and/or prevent micro-trenching in the final stack (e.g., the stack 140 containing the insulative structures 106 and the conductive structures 144). For example, the isolation structures 138 may be utilized to substantially reduce ion deflection off of sidewalls defining the slots near the intersections 130 during formation while providing an etch profile that substantially reduces (e.g., substantially prevents) micro-trenching by eliminating corners between the converging slots within the intersection regions 136. Therefore, forming the isolation structures 138 within the isolation region 120 to laterally separate the slots from one another (e.g., by providing linear slots without forming the intersections 130 therebetween) may prevent the ions from being deflected into the stack 102 near the intersections 130 and causing micro-trenching in the stack 102. Moreover, by preventing micro-trenching in the stack 102, the methods and structures described herein provide one or more of improved performance, reliability, and durability, lower costs, increased miniaturization of components, improved pattern quality, and greater packaging density as compared to conventional devices and conventional systems.

In addition, in some conventional electronic devices, the proximity of first slots to a second slot and/or block openings near intersections may result in so-called “overetch” during processing. For example, if the first slots were to intersect the second slot and/or the block openings, then overetch of tier materials of tiers of a stack may occur proximate the intersections during formation of the slots. In some instances, damage may occur at the intersections during subsequent processing acts. Thus, the first slots 126, according to embodiments of the disclosure, may be separated from the second slot 128 and/or the block openings 148 by the isolation structures 138 within the isolation region 120 prior to performing additional processing acts, as described herein.

Further, in some instances, damage may occur to pillars and to support structures during formation of conventional slots. Particularly, damage to the materials of the pillars and support structures, also called “clipping,” may be a source of defects, which can adversely affect electronic device performance. Accordingly, the isolation structures 138 of the isolation region 120 may be laterally interposed between the first slots 126 and the second slot 128 and/or the block openings 148 in order to substantially reduce (e.g., substantially prevent) damage to the first pillars 104, the second pillars 105, and the support structures 127 during fabrication. Moreover, formation of the isolation structures 138 within the isolation region 120 may provide increased structural support within the stack 140, without undesirably increasing the overall width (e.g., horizontal footprint) of the stack 140 within the array region.

Accordingly, in some embodiments, an electronic device comprises a stack comprising an alternating sequence of conductive structures and insulative structures arranged in tiers, and at least one dielectric-filled slot extending vertically through the stack and extending in a first horizontal direction. The at least one dielectric-filled slot is defined between two internal sidewalls of the stack. The electronic device comprises additional dielectric-filled slots extending vertically through the stack and extending in a second horizontal direction transverse to the first horizontal direction, and isolation structures laterally interposed between the at least one dielectric-filled slot and the additional dielectric-filled slots. The isolation structures are laterally adjacent to the conductive structures of the stack, and at least some of the isolation structures are vertically adjacent to the insulative structures of the stack.

Accordingly, in further embodiments, an electronic device comprises a stack comprising tiers of alternating conductive structures and insulative structures overlying a source, and pillars extending vertically through the stack and to the source. At least some of the pillars comprise a channel material. The electronic device comprises dielectric block structures extending vertically through the stack. The dielectric block structures are defined between two internal sidewalls of the stack and spaced apart from one another in a first horizontal direction. The electronic device comprises dielectric-filled slots extending vertically through the stack and extending in a second horizontal direction that is substantially orthogonal to the first horizontal direction. Isolation structures separate the dielectric block structures from the dielectric-filled slots. The isolation structures are at an elevational level of the conductive structures of the stack.

Accordingly, in at least some embodiments, a method of forming an electronic device comprises forming a stack comprising an alternating sequence of insulative structures and additional insulative structures arranged in tiers over a source, and forming at least one slot through the stack to expose the source. The at least one slot extends in a first horizontal direction and is defined between two internal sidewalls of the stack. The method comprises forming additional slots through the stack and extending in a second horizontal direction transverse to the first horizontal direction, and forming isolation structures laterally interposed between the at least one slot and the additional slots. At least some of the isolation structures are vertically adjacent to the insulative structures of the stack. The method comprises replacing portions of the additional insulative structures with conductive material to form conductive structures laterally adjacent to the isolation structures, and forming a dielectric material within the at least one slot and the additional slots. The isolation structures laterally separate the dielectric material of the at least one slot from the dielectric material of the additional slots.

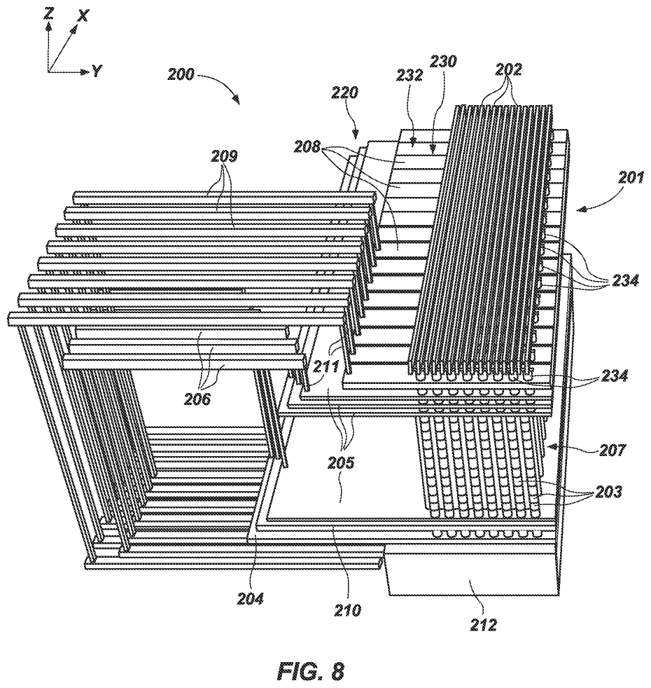

FIG. 8 illustrates a partial cutaway perspective view of a portion of an electronic device 200 (e.g., a microelectronic device, a memory device, such as a 3D NAND Flash memory device) including one or more electronic device structures 201 (e.g., a microelectronic device structure). The electronic device 200 may be substantially similar to the electronic devices 100, 100′ previously described with reference to FIGS. 1A through 7D. As shown in FIG. 8, the electronic device structure 201 of the electronic device 200 may include a staircase structure 220 defining contact regions for connecting interconnect lines 206 to conductive structures 205 (e.g., corresponding to the conductive structures 144 (FIGS. 5B and 7B)). The electronic device structure 201 may include vertical strings 207 of memory cells 203 (e.g., vertical strings of memory cells of the first pillars 104 (FIGS. 5B and 7B)) that are coupled to each other in series. The vertical strings 207 may extend vertically (e.g., in the Z-direction) and orthogonally to conductive lines and the conductive structures 205, such as the data lines 202, a source tier 204 (e.g., corresponding to the source tier 112 (FIGS. 5B and 7B)), the interconnect lines 206, first select gates 208 (e.g., upper select gates, drain select gates (SGDs)), select lines 209, and a second select gate 210 (e.g., a lower select gate, a source select gate (SGS)). The select gates 208 may be horizontally divided (e.g., in the Y-direction) into multiple blocks 232 (e.g., corresponding to the blocks 132 (FIGS. 2A and 6A)) horizontally separated (e.g., in the X-direction) from one another by slots 230 (e.g., corresponding to the first slots 126 (FIGS. 2A and 6A)).

Vertical conductive contacts 211 may electrically couple components to each other as shown. For example, the select lines 209 may be electrically coupled to the first select gates 208 and the interconnect lines 206 may be electrically coupled to the conductive structures 205. The electronic device 200 may also include a control unit 212 (e.g., corresponding to the base structure 114 (FIGS. 5B and 7B)) positioned under the memory array, which may include at least one of string driver circuitry, pass gates, circuitry for selecting gates, circuitry for selecting conductive lines (e.g., the data lines 202, the interconnect lines 206), circuitry for amplifying signals, and circuitry for sensing signals. The control unit 212 may be electrically coupled to the data lines 202, the source tier 204, the interconnect lines 206, the first select gates 208, and the second select gates 210, for example. In some embodiments, the control unit 212 includes CMOS (complementary metal-oxide-semiconductor) circuitry. In such embodiments, the control unit 212 may be characterized as having a “CMOS under Array” (“CuA”) configuration.

The first select gates 208 may extend horizontally in a first direction (e.g., the X-direction) and may be coupled to respective first groups of vertical strings 207 of memory cells 203 at a first end (e.g., an upper end) of the vertical strings 207. The second select gate 210 may be formed in a substantially planar configuration and may be coupled to the vertical strings 207 at a second, opposite end (e.g., a lower end) of the vertical strings 207 of memory cells 203.

The data lines 202 (e.g., digit lines, bit lines) may extend horizontally in a second direction (e.g., in the Y-direction) that is at an angle (e.g., perpendicular) to the first direction in which the first select gates 208 extend. Individual data lines 202 may be coupled to individual groups of the vertical strings 207 extending the second direction (e.g., the Y-direction) at the first end (e.g., the upper end) of the vertical strings 207 of the individual groups. Additional individual groups of the vertical strings 207 extending the first direction (e.g., the X-direction) and coupled to individual first select gates 208 may share a particular vertical string 207 thereof with individual group of vertical strings 207 coupled to an individual data line 202. Thus, an individual vertical string 207 of memory cells 203 may be selected at an intersection of an individual first select gate 208 and an individual data line 202. Accordingly, the first select gates 208 may be used for selecting memory cells 203 of the vertical strings 207 of memory cells 203.

The conductive structures 205 (e.g., word lines) may extend in respective horizontal planes. The conductive structures 205 may be stacked vertically, such that each conductive structure 205 is coupled to at least some of the vertical strings 207 of memory cells 203, and the vertical strings 207 of the memory cells 203 extend vertically through the stack including the conductive structures 205. The conductive structures 205 may be coupled to or may form control gates of the memory cells 203.

The first select gates 208 and the second select gates 210 may operate to select a vertical string 207 of the memory cells 203 interposed between data lines 202 and the source tier 204. Thus, an individual memory cell 203 may be selected and electrically coupled to a data line 202 by operation of (e.g., by selecting) the appropriate first select gate 208, second select gate 210, and conductive structure 205 that are coupled to the particular memory cell 203.

The staircase structure 220 may be configured to provide electrical connection between the interconnect lines 206 and the conductive structures 205 through the vertical conductive contacts 211. In other words, an individual conductive structure 205 may be selected via an interconnect line 206 in electrical communication with a respective vertical conductive contact 211 in electrical communication with the conductive structure 205. The data lines 202 may be electrically coupled to the vertical strings 207 through conductive contact structures 234.

Electronic devices (e.g., the electronic devices 100, 100′, 200) including the isolation structures 138 of the isolation region 120 laterally interposed between at least one dielectric-filled slot (e.g., the dielectric material in the second slot 128, dielectric material in the block openings 148) and additional dielectric-filled slots (e.g., dielectric material in the first slots 126), according to embodiments of the disclosure, may be used in embodiments of electronic systems of the disclosure. For example, FIG. 9 is a block diagram of an electronic system 303, in accordance with embodiments of the disclosure. The electronic system 303 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 303 includes at least one memory device 305. The memory device 305 may include, for example, an embodiment of an electronic device previously described herein (e.g., the electronic devices 100, 100′, 200 previously described with reference to FIGS. 1A through 7D and FIG. 8) including the isolation structures 138 of the isolation region 120 laterally interposed between at least one dielectric-filled slot and additional dielectric-filled slots.

The electronic system 303 may further include at least one electronic signal processor device 307 (often referred to as a “microprocessor”). The electronic signal processor device 307 may optionally include an embodiment of an electronic device previously described herein (e.g., one or more of the electronic devices 100, 100′, 200 previously described with reference to FIGS. 1A through 7D and FIG. 8). The electronic system 303 may further include one or more input devices 309 for inputting information into the electronic system 303 by a user, such as, for example, a mouse or other pointing device, a keyboard, a touchpad, a button, or a control panel. The electronic system 303 may further include one or more output devices 311 for outputting information (e.g., visual or audio output) to a user such as, for example, a monitor, a display, a printer, an audio output jack, a speaker, etc. In some embodiments, the input device 309 and the output device 311 may comprise a single touchscreen device that can be used both to input information to the electronic system 303 and to output visual information to a user. The input device 309 and the output device 311 may communicate electrically with one or more of the memory device 305 and the electronic signal processor device 307.

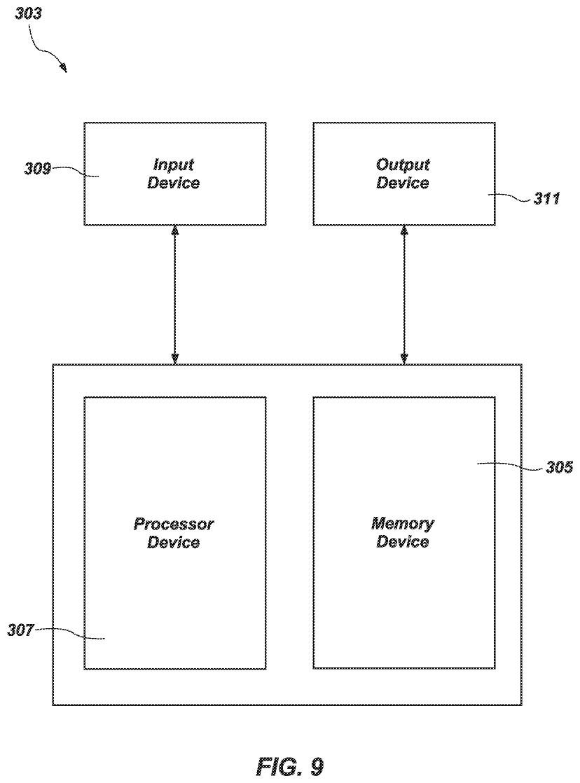

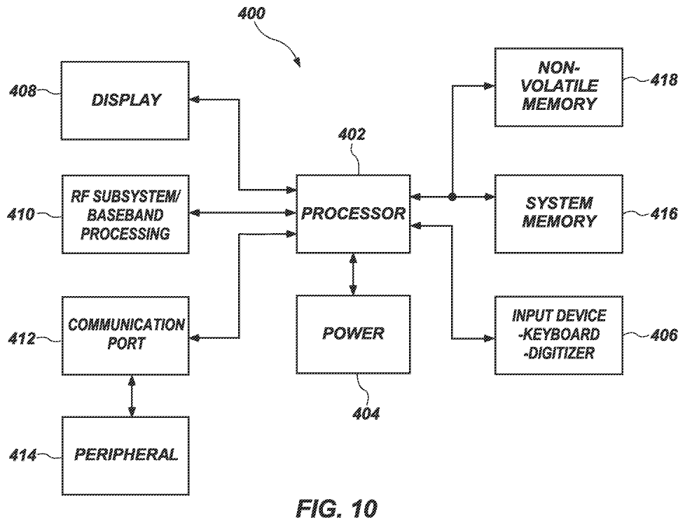

With reference to FIG. 10, depicted is a processor-based system 400. The processor-based system 400 may include various electronic devices (e.g., the electronic devices 100, 100′, 200) manufactured in accordance with embodiments of the present disclosure. The processor-based system 400 may be any of a variety of types such as a computer, pager, cellular phone, personal organizer, control circuit, or other electronic device. The processor-based system 400 may include one or more processors 402, such as a microprocessor, to control the processing of system functions and requests in the processor-based system 400. The processor 402 and other subcomponents of the processor-based system 400 may include electronic devices (e.g., the electronic devices 100, 100′, 200) manufactured in accordance with embodiments of the present disclosure.

The processor-based system 400 may include a power supply 404 in operable communication with the processor 402. For example, if the processor-based system 400 is a portable system, the power supply 404 may include one or more of a fuel cell, a power scavenging device, permanent batteries, replaceable batteries, and rechargeable batteries. The power supply 404 may also include an AC adapter; therefore, the processor-based system 400 may be plugged into a wall outlet, for example. The power supply 404 may also include a DC adapter such that the processor-based system 400 may be plugged into a vehicle cigarette lighter or a vehicle power port, for example.

Various other devices may be coupled to the processor 402 depending on the functions that the processor-based system 400 performs. For example, a user interface 406 may be coupled to the processor 402. The user interface 406 may include input devices such as buttons, switches, a keyboard, a light pen, a mouse, a digitizer and stylus, a touch screen, a voice recognition system, a microphone, or a combination thereof. A display 408 may also be coupled to the processor 402. The display 408 may include an LCD display, an SED display, a CRT display, a DLP display, a plasma display, an OLED display, an LED display, a three-dimensional projection, an audio display, or a combination thereof. Furthermore, an RF sub-system/baseband processor 410 may also be coupled to the processor 402. The RF sub-system/baseband processor 410 may include an antenna that is coupled to an RF receiver and to an RF transmitter (not shown). A communication port 412, or more than one communication port 412, may also be coupled to the processor 402. The communication port 412 may be adapted to be coupled to one or more peripheral devices 414, such as a modem, a printer, a computer, a scanner, or a camera, or to a network, such as a local area network, remote area network, intranet, or the Internet, for example.

The processor 402 may control the processor-based system 400 by implementing software programs stored in the memory. The software programs may include an operating system, database software, drafting software, word processing software, media editing software, or media playing software, for example. The memory is operably coupled to the processor 402 to store and facilitate execution of various programs. For example, the processor 402 may be coupled to system memory 416, which may include one or more of spin torque transfer magnetic random access memory (STT-MRAM), magnetic random access memory (MRAM), dynamic random access memory (DRAM), static random access memory (SRAM), racetrack memory, and other known memory types. The system memory 416 may include volatile memory, non-volatile memory, or a combination thereof. The system memory 416 is typically large so that it can store dynamically loaded applications and data. In some embodiments, the system memory 416 may include semiconductor devices, such as the electronic devices (e.g., the electronic devices 100, 100′, 200) described above, or a combination thereof.

The processor 402 may also be coupled to non-volatile memory 418, which is not to suggest that system memory 416 is necessarily volatile. The non-volatile memory 418 may include one or more of STT-MRAM, MRAM, read-only memory (ROM) such as an EPROM, resistive read-only memory (RROM), and flash memory to be used in conjunction with the system memory 416. The size of the non-volatile memory 418 is typically selected to be just large enough to store any necessary operating system, application programs, and fixed data. Additionally, the non-volatile memory 418 may include a high-capacity memory such as disk drive memory, such as a hybrid-drive including resistive memory or other types of non-volatile solid-state memory, for example. The non-volatile memory 418 may include electronic devices, such as the electronic devices (e.g., the electronic devices 100, 100′, 200) described above, or a combination thereof.

Accordingly, in at least some embodiments, a system comprises a processor operably coupled to an input device and an output device, and one or more electronic devices operably coupled to the processor. The one or more electronic devices comprise strings of memory cells extending vertically through a tiered stack comprising a vertically alternating sequence of insulative structures and conductive structures, and slot structures extending vertically through the tiered stack and separating the tiered stack into blocks. Each of the blocks comprise some of the strings of memory cells. The one or more electronic devices comprise at least one additional slot structure extending vertically through the tiered stack and extending in a horizontal direction that is substantially orthogonal to another horizontal direction in which the slot structures extend, and opposing isolation regions laterally separating the at least one additional slot structure from the conductive structures of the tiered stack. The opposing isolation regions comprise a barrier material between vertically neighboring insulative structures of the tiered stack and located outside of a horizontal area of the at least one additional slot structure.

The electronic devices and systems of the disclosure advantageously facilitate one or more of improved simplicity, greater packaging density, and increased miniaturization of components as compared to conventional devices and conventional systems. The methods of the disclosure facilitate the formation of devices (e.g., apparatuses, microelectronic devices, memory devices) and systems (e.g., electronic systems) having one or more of improved performance, reliability, and durability, lower costs, increased yield, increased miniaturization of components, improved pattern quality, and greater packaging density as compared to conventional devices (e.g., conventional apparatuses, conventional electronic devices, conventional memory devices) and conventional systems (e.g., conventional electronic systems).

While certain illustrative embodiments have been described in connection with the figures, those of ordinary skill in the art will recognize and appreciate that embodiments encompassed by the disclosure are not limited to those embodiments explicitly shown and described herein. Rather, many additions, deletions, and modifications to the embodiments described herein may be made without departing from the scope of embodiments encompassed by the disclosure, such as those hereinafter claimed, including legal equivalents. In addition, features from one disclosed embodiment may be combined with features of another disclosed embodiment while still being encompassed within the scope of the disclosure.

What is claimed is:

1. An electronic device, comprising:
a stack comprising an alternating sequence of conductive structures and insulative structures arranged in tiers;
at least one dielectric-filled slot extending vertically through the stack and extending in a first horizontal direction, the at least one dielectric-filled slot defined between two internal sidewalls of the stack;
additional dielectric-filled slots extending vertically through the stack and extending in a second horizontal direction transverse to the first horizontal direction; and
isolation structures laterally interposed between the at least one dielectric-filled slot and the additional dielectric-filled slots, the isolation structures laterally adjacent to the conductive structures of the stack, and at least some of the isolation structures vertically adjacent to the insulative structures of the stack.

2. The electronic device of claim 1, wherein the additional dielectric-filled slots divide the stack into blocks comprising memory pillars, the isolation structures external to the at least one dielectric-filled slot and horizontally overlapping ends of the additional dielectric-filled slots.

3. The electronic device of claim 1, wherein the additional dielectric-filled slots directly contact the isolation structures without contacting the at least one dielectric-filled slot.

4. The electronic device of claim 1, wherein the at least one dielectric-filled slot tapers in width from a broadest width at a top of the stack to a narrowest width at a bottom of the stack, a thickness of the isolation structures at the bottom of the stack is relatively greater than a thickness of the isolation structures at the top of the stack.

5. The electronic device of claim 1, wherein the isolation structures directly contact the conductive structures of the stack along vertical interfaces therebetween, and the isolation structures directly contact the insulative structures of the stack along horizontal interfaces therebetween.

6. The electronic device of claim 1, wherein a material composition of the isolation structures is substantially the same as a material composition of one or more of the at least one dielectric-filled slot, the additional dielectric-filled slots, and the insulative structures of the stack.

7. An electronic device, comprising:
a stack comprising tiers of alternating conductive structures and insulative structures overlying a source;
pillars extending vertically through the stack and to the source, at least some of the pillars comprising a channel material;
dielectric block structures extending vertically through the stack, the dielectric block structures defined between two internal sidewalls of the stack and spaced apart from one another in a first horizontal direction;
dielectric-filled slots extending vertically through the stack and extending in a second horizontal direction that is substantially orthogonal to the first horizontal direction; and
isolation structures separating the dielectric block structures from the dielectric-filled slots, the isolation structures at an elevational level of the conductive structures of the stack.

8. The electronic device of claim 7, further comprising support structures extending vertically through the stack and laterally adjacent to the dielectric-filled slots, the support structures and the isolation structures comprising an oxide material.

9. The electronic device of claim 7, wherein sidewalls of the isolation structures abut portions of the conductive structures of the stack at a location external to vertical interfaces between the dielectric block structures and the isolation structures, the dielectric block structures directly contacting the isolation structures along the vertical interfaces therebetween.

10. The electronic device of claim 7, wherein one of the dielectric-filled slots is adjacent to one of the dielectric block structures in the second horizontal direction.

11. The electronic device of claim 7, wherein a width of individual dielectric block structures in the first horizontal direction is greater than a width of individual dielectric-filled slots in the first horizontal direction.

12. The electronic device of claim 7, wherein an outer boundary of an isolation region including the isolation structures is relatively wider than outer boundaries of the dielectric block structures in the second horizontal direction.

13. The electronic device of claim 7, wherein end surfaces of the isolation structures and the insulative structures of the stack proximal the dielectric block structures are substantially aligned with one another, and end surfaces of the conductive structures of the stack proximal the dielectric block structures are horizontally recessed relative to the end surfaces of the insulative structures.

14. A method of forming an electronic device, the method comprising:
forming a stack over a source, the stack comprising an alternating sequence of insulative structures and additional insulative structures arranged in tiers;
forming at least one slot through the stack to expose the source, the at least one slot extending in a first horizontal direction and defined between two internal sidewalls of the stack;
forming additional slots through the stack and extending in a second horizontal direction transverse to the first horizontal direction;
forming isolation structures laterally interposed between the at least one slot and the additional slots, at least some of the isolation structures vertically adjacent to the insulative structures of the stack;
replacing portions of the additional insulative structures with conductive material to form conductive structures laterally adjacent to the isolation structures; and
forming a dielectric material within the at least one slot and the additional slots, the isolation structures laterally separating the dielectric material of the at least one slot from the dielectric material of the additional slots.

15. The method of claim 14, further comprising forming memory pillars through the tiers prior to forming the at least one slot, the isolation structures laterally adjacent to the memory pillars and separated therefrom by the conductive structures of the stack.

16. The method of claim 14, wherein forming the at least one slot comprises forming individual dielectric block structures extending in the first horizontal direction, the individual dielectric block structures spaced apart from one another in the first horizontal direction.

17. The method of claim 16, wherein:
forming the individual dielectric block structures comprises forming discrete openings extending vertically through the stack, the discrete openings laterally separated from one another by isolation regions comprising materials of the stack; and
forming the dielectric material within the at least one slot comprises forming segmented portions of the dielectric material within the discrete openings.

18. The method of claim 14, wherein forming the additional slots comprises forming the additional slots substantially simultaneously with forming the at least one slot, each of the at least one slot and the additional slots formed to extend from a vertically uppermost boundary of a vertically uppermost tier of the stack to a vertically lowermost boundary of a vertically lowermost tier of the stack.

19. The method of claim 14, further comprising:
forming openings laterally adjacent to at least some of the additional slots; and
forming support structures within the openings prior to forming the conductive structures.

20. The method of claim 19, further comprising forming the openings during formation of one or more of the at least one slot and the additional slots, wherein a critical dimension of the openings is substantially the same as a width of the at least one slot in the first horizontal direction.

21. The method of claim 19, wherein:
forming the support structures comprises completely forming the support structures prior to forming the at least one slot and the additional slots; and
forming the additional slots comprises forming the additional slots after forming the at least one slot and the openings.

22. The method of claim 14, wherein forming the isolation structures comprises recessing end portions of the additional insulative structures through the at least one slot using one or more material removal processes, without recessing end portions of an oxide material of the insulative structures adjacent to the at least one slot.

23. The method of claim 14, wherein forming the at least one slot and the additional slots comprises initially forming the additional slots to intersect the at least one slot and thereafter separating the additional slots from the at least one slot with the isolation structures.

24. The method of claim 14, wherein forming the at least one slot and the additional slots comprises forming the additional slots adjacent to the at least one slot without the additional slots intersecting the at least one slot.

25. A system, comprising:
a processor operably coupled to an input device and an output device; and
one or more electronic devices operably coupled to the processor, the one or more electronic devices comprising:
strings of memory cells extending vertically through a tiered stack comprising a vertically alternating sequence of insulative structures and conductive structures;
slot structures extending vertically through the tiered stack and separating the tiered stack into blocks, each of the blocks comprising some of the strings of memory cells;
at least one additional slot structure extending vertically through the tiered stack and extending in a horizontal direction that is substantially orthogonal to another horizontal direction in which the slot structures extend; and
opposing isolation regions laterally separating the at least one additional slot structure from the conductive structures of the tiered stack, the opposing isolation regions comprising a barrier material between vertically neighboring insulative structures of the tiered stack and located outside of a horizontal area of the at least one additional slot structure.

26. The system of claim 25, wherein the barrier material comprises a material that is non-reactive with a conductive material of the conductive structures.
